(19) United States
(12) Patent Application Publication
(10) Pub. No.: US 2024/0298469 A1
(43) Pub. Date: Sep. 5, 2024

(54) DISPLAY DEVICE

(71) Applicant: Kazuatsu ITO, Kameyama City , Mie (JP)

(72) Inventor: Kazuatsu ITO, Kameyama City , Mie (JP)

(21) Appl. No.: 18/569,845

(22) PCT Filed: Jul. 6, 2021
(86) PCT No.: PCT/JP2021/025465

§ 371 Date: Dec. 13, 2023

(51) Int. Cl. H10K 59/121; H10K 59/35

(52) U.S. Cl. CPC H10K 59/1213; H10K 59/353

(57) ABSTRACT

A display device includes: a substrate layer; a thin-film transistor layer; and a light-emitting element layer, the light-emitting element layer including a light-emitting element provided in a subpixel constituting a display region, the thin-film transistor layer including a plurality of thin-film transistors provided in the subpixel, the plurality of thin-film transistors being configured to control an operation of the light-emitting element, to display an image in the display region by light emission, wherein the subpixel located in a middle of the display region is a first subpixel, and the subpixel located at an outer edge of the display region is a second subpixel, and wherein a channel length of at least one of the plurality of thin-film transistors provided in the second subpixel is shorter than a channel length of one of the plurality of thin-film transistors provided in the first subpixel and having an identical function.

### TECHNICAL FIELD

The present disclosure relates to a display device.

### BACKGROUND ART

Organic EL displays provided with organic electroluminescence (hereinafter referred to as EL) elements have been recently commercialized. An organic EL display includes a plurality of thin-film transistors (hereinafter also referred to as TFTs) provided for each subpixel, which is the minimum unit of an image. A semiconductor layer made of an oxide semiconductor, such as In—Ga—Zn—O, is known as a semiconductor layer that constitutes TFTs (see Patent Literature 1 for instance).

### CITATION LIST

### Patent Literature

Patent Literature 1: Japanese Unexamined Patent Application Publication No. 2019-078788

### SUMMARY

### Technical Problem

By the way, in such an organic EL display, the pattern densities of various wires and the pattern densities of various contacts are different between the outer edge of its display region, where an image is to be displayed, and the middle of the display region. Consequently, The TFT's ON-current properties in a subpixel located at the outer periphery of the display region are reduced more easily than those in a subpixel located in the middle of the display region. This possibly causes a bright spot in the subpixel when the organic EL display performs dark display or low-grayscale display.

The present disclosure aims to prevent a bright spot in a subpixel located at the outer edge of a display region.

### Solution to Problem

The technique of the present disclosure is directed to a display device including the following: a substrate layer; a TFT layer provided on the substrate layer; and a light-emitting element layer provided on the TFT layer. In the display device according to the technique of the present disclosure, the light-emitting element layer includes a light-emitting element provided in a subpixel constituting a display region. The TFT layer includes a plurality of TFTs provided in the subpixel. In the display device, the plurality of TFTs control the operation of the light-emitting element, to display an image in the display region by light emission from the light-emitting element.

Moreover, the subpixel located in the middle of the display region is a first subpixel, the subpixel located at the outer edge of the display region is a second subpixel, and the channel length of at least one of the plurality of TFTs provided in the second subpixel is shorter than the channel length of one of the plurality of TFTs provided in the first subpixel and having an identical function. Alternatively, the channel width of at least one of the plurality of TFTs provided in the second subpixel is wider than the channel width of one of the plurality of TFTs provided in the first subpixel and having an identical function. Alternatively, at least one of the plurality of TFTs provided in the second subpixel is a TFT of multi-gate structure, and one of the plurality of TFTs provided in the first subpixel and having a function identical to that of the TFT of multi-gate structure in the second subpixel is a TFT of single-gate structure.

### Advantageous Effect of Disclosure

The technique of the present disclosure can prevent a bright spot in a subpixel located at the outer edge of the display region of a display device.

### BRIEF DESCRIPTION OF DRAWINGS

FIG. 1 is a plan view of the schematic configuration of an organic EL display.

FIG. 2 is a plan view of pixels constituting a display region, and of various display wires.

FIG. 3 is a sectional view of the organic EL display taken along line III-III in FIG. 2.

FIG. 4 is a sectional view (left side) of a first TFT, and a sectional view (right side) of a second TFT.

FIG. 5 is a sectional view of the stacked structure of an organic EL layer.

FIG. 6 is an equivalent-circuit diagram illustrating a pixel circuit.

FIG. 7 is a schematic plan view of the configuration of subpixels constituting the display region.

FIG. 8 is a schematic plan view of a compensation TFT provided in a first subpixel according to the first embodiment.

FIG. 9 is a schematic plan view of the compensation TFT provided in a second subpixel according to the first embodiment.

FIG. 10 is a sectional view (left side) of the compensation TFT taken along line A-A in FIG. 8, and a sectional view (right side) of the compensation TFT taken along line B-B in FIG. 9.

FIG. 11 is a schematic plan view of the compensation TFT provided in the second subpixel according to a first modification of the first embodiment.

FIG. 12 is a sectional view (left side) of the compensation TFT taken along line A-A in FIG. 8, and a sectional view (right side) of the compensation TFT taken along line C-C in FIG. 11.

FIG. 13 is a schematic plan view of the compensation TFT provided in the second subpixel according to a second modification of the first embodiment.

FIG. 14 is a sectional view (left side) of the compensation TFT taken along line A-A in FIG. 8, and a sectional view (right side) of the compensation TFT taken along line D-D in FIG. 13.

FIG. 15 is a schematic plan view of the configuration of subpixels constituting the display region according to a second embodiment.

FIG. 16 is a schematic plan view of the compensation TFT provided in a third subpixel according to the second embodiment.

FIG. 17 is a schematic plan view of the compensation TFT provided in a fourth subpixel according to the second embodiment.

FIG. 18 is a sectional view (left side) of the compensation TFT taken along line A-A in FIG. 8, a sectional view (middle) of the compensation TFT taken along line E-E in FIG. 16, and a sectional view (right sight) of the compensation TFT taken along line F-F in FIG. 17.

FIG. 19 is a schematic plan view of the compensation TFT provided in the third subpixel according to a modification of the second embodiment.

FIG. 20 is a schematic plan view of the compensation TFT provided in the fourth subpixel according to the modification of the second embodiment.

FIG. 21 is a sectional view (left side) of the compensation TFT taken along line A-A in FIG. 8, a sectional view (middle) of the compensation TFT taken along line G-G in FIG. 19, and a sectional view (right sight) of the compensation TFT taken along line H-H in FIG. 20.

FIG. 22 is a schematic plan view of the compensation TFT provided in the third subpixel according to a third embodiment.

FIG. 23 is a schematic plan view of the compensation TFT provided in the fourth subpixel according to the third embodiment.

FIG. 24 is a sectional view (left side) of the compensation TFT taken along line A-A in FIG. 8, a sectional view (middle) of the compensation TFT taken along line J-J in FIG. 22, and a sectional view (right sight) of the compensation TFT taken along line K-K in FIG. 23.

FIG. 25 is a schematic plan view of the compensation TFT provided in the third subpixel according to a modification of the third embodiment.

FIG. 26 is a schematic plan view of the compensation TFT provided in the fourth subpixel according to the modification of the third embodiment.

FIG. 27 is a sectional view (left side) of the compensation TFT taken along line A-A in FIG. 8, a sectional view (middle) of the compensation TFT taken along line L-L in FIG. 25, and a sectional view (right sight) of the compensation TFT taken along line M-M in FIG. 26.

FIG. 28 is a schematic plan view of the configuration of subpixels constituting the display region according to a fourth embodiment.

### DESCRIPTION OF EMBODIMENTS

Example embodiments will be detailed on the basis of the drawings. The following embodiments will describe, by way of example, an organic EL display including organic EL elements as a display device according to the technique of the present disclosure.

It is noted that in the following embodiments, that a constituent, such as a film, a layer, or an element, is provided or formed on another constituent, such as a film, a layer, or an element, means not only that the constituent is directly on the other constituent, but also that a constituent, such as a film, a layer, or an element, is interposed between these constituents.

It is also noted that in the following embodiments, unless otherwise specified, that a constituent, such as a film, a layer, or an element, is connected to another constituent, such as a film, a layer, or an element, means that these constituents are electrically connected together. Within a range not departing from the purport of the technique of the present disclosure, this description encompasses not only a direct connection, but also an indirection connection with the intervention of a constituent, such as a film, a layer, or an element. This description further encompasses an instance where a constituent is integrated with another constituent; that is, part of the constituent constitutes the other constituent.

It is also noted that in the following embodiments, that a constituent, such as a film, a layer, or an element, is in the same layer as another constituent, such as a film, a layer, or an element, means that the constituent is formed in the same process step as the other constituent. That a constituent is under another constituent means that the constituent is formed in a process step anterior to that for forming the other constituent. That a constituent is over another constituent means that the constituent is formed in a process step posterior to that for forming the other constituent.

It is also noted that in the following embodiments, that a constituent, such as a film, a layer, or an element, is identical to or equivalent to another constituent, such as a film, a layer, or an element, means not only that the constituent is completely identical to or completely equivalent to the other constituent, but also that the constituent and the other constituent are substantially identical or substantially equivalent though they are different within a range of manufacturing variation or tolerance.

It is also noted that the following embodiments use ordinal numbers, such as first, second, third and others, in order to distinguish words provided with these ordinal numbers from each other and do not limit numerals or an order of some kind.

### First Embodiment

An organic EL display 1 according to this embodiment is used as a display for mobile apparatuses, including smartphones and tablet terminals, and for various apparatuses, including personal computers (PCs) and TV sets.

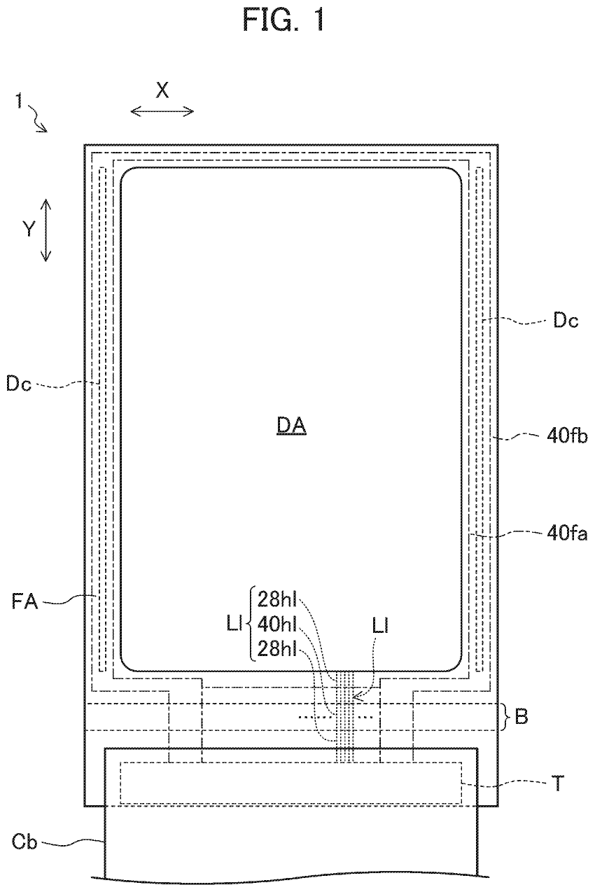

As illustrated in FIG. 1, the organic EL display has a display region DA and a frame region FA. The display region DA constitutes a screen. The display region DA is a region for displaying an image. The frame region FA constitutes a non-display part other than the screen. The frame region FA is a region for not displaying an image.

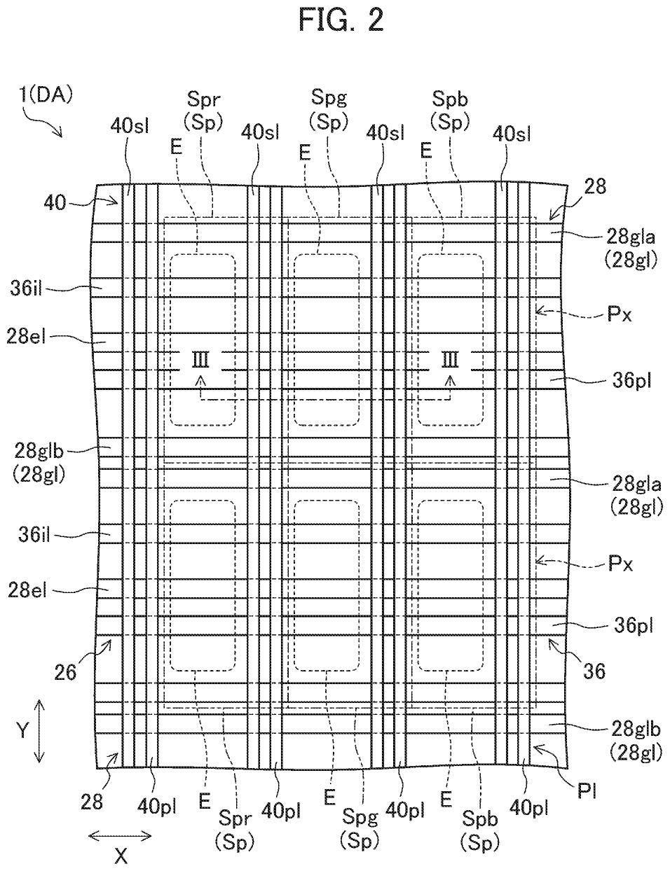

The display region DA is provided in a rectangular shape. Although this embodiment describes, by way of example, the display region DA having a rectangular shape, the display region DA may have a substantially rectangular shape, such as a shape with at least one of the sides being arc-shaped, a shape with at least one of the corners being arc-shaped, or a shape with at least one of the sides being cut partly. As illustrated in FIG. 2, the display region DA is composed of a plurality of pixels Px.

The plurality of pixels Px are arranged in matrix. Each pixel Px is composed of three subpixels Sp. These three subpixels Sp are a subpixel Spr having a light-emitting region E where red light is emitted, a pixel Spg having a light-emitting region E where green light is emitted, and a subpixel Spb having a light-emitting region E where blue light is emitted. These three subpixels Spr, Spg and Spb are arranged in a stripe shape for instance.

As illustrated in FIG. 1, the frame region FA is provided in a rectangular shape. A terminal section T for connecting to an external circuit (e.g., a display control circuit) is provided in a portion constituting one of the sides of the frame region FA. A bending section B bendable about a first direction X, which is the lateral direction in FIG. 1, is provided between the display region DA and terminal section T in the frame region FA.

The terminal section T is disposed on the backside of the organic EL display 1 when the frame region FA is, for instance, 1800 (U-shape) bent along the bending section B. In the terminal section T is connected to a wiring board Cb, an example of which is a flexible printed circuit (FPC). The frame region FA is provided with a plurality of routed wires L1. The plurality of routed wires L1 are each routed from the display region DA to the terminal section T.

Each routed wire L1 is connected to the display control circuit (not shown) via the wiring board Cb in the terminal section T. The display control circuit is a circuit that controls image display by supplying a signal to display wires (e.g., source wires 40sl) and drive circuits Dc. Each routed wire L1 is composed of a lower routed wire 28hl and an upper routed wire 40hl.

The drive circuit Dc are provided in a monolithic manner in the frame region FA. The drive circuits Dc are disposed in respective portions constituting sides (the right and left sides in FIG. 1) of the frame region FA adjacent to the side along which the terminal section T is provided. The drive circuits Dc include a gate driver and an emission driver. The frame region FA is provided with a first frame wire 40fa and a second frame wire 40fb.

The first frame wire 40fa extends so as to surround the display region DA. The first frame wire 40fa extends to the terminal section T. The first frame wire 40fa is supplied with a high-level power-supply voltage (ELVDD) via the wiring board Cb in the terminal section T. The second frame wire 40fb is provided in a C-shape. The second frame wire 40fb has both ends extending to the terminal section T along the first frame wire 40fa. The second frame wire 40fb is supplied with a low-level power-supply voltage (ELVSS) via the wiring board Cb in the terminal section T.

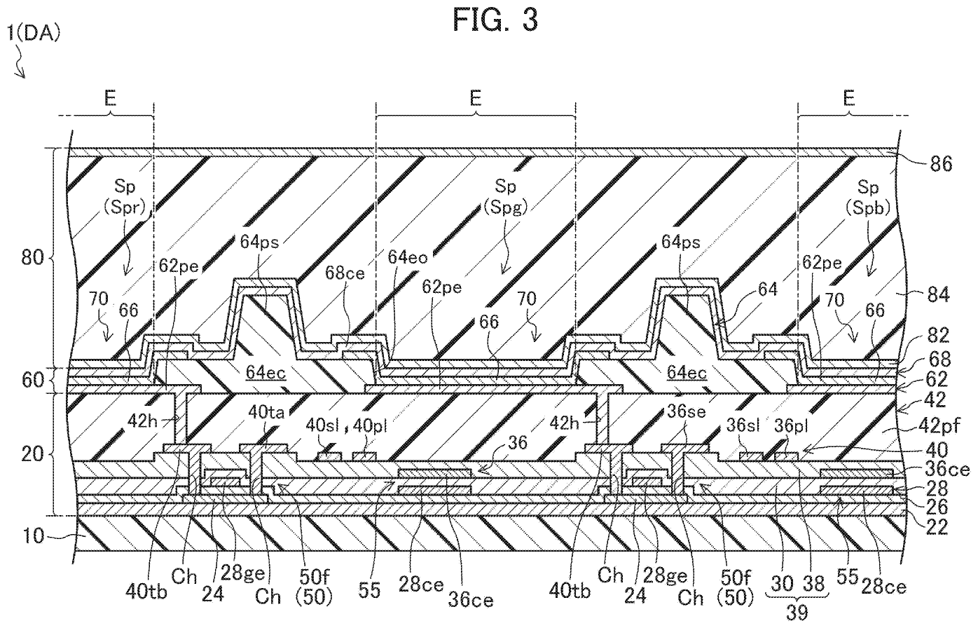

The organic EL display 1 operates under an active-matrix driving scheme, where light emission in each subpixel Sp is controlled by TFTs 50, and where image display is performed by the operation of the TFTs 50. As illustrated in FIG. 3, a display panel DP includes the following: a substrate layer 10; a TFT layer 20 provided over the substrate layer 10; a light-emitting element layer 60 provided over the TFT layer 20; and a sealing film 80 provided over the light-emitting element layer 60.

### Substrate Layer

The substrate layer 10 is a layer constituting the base of the display panel. The substrate layer 10 has flexibility. The substrate layer 10 is formed of an organic resin material, such as polyimide resin, polyamide resin, or epoxy resin. The substrate layer 10 may be composed of a stack of an inorganic insulating layer made of an inorganic insulating material, such as silicon oxide, silicon nitride, or silicon nitride oxide, and a resin layer made of such an organic resin material as described above.

### TFT Layer

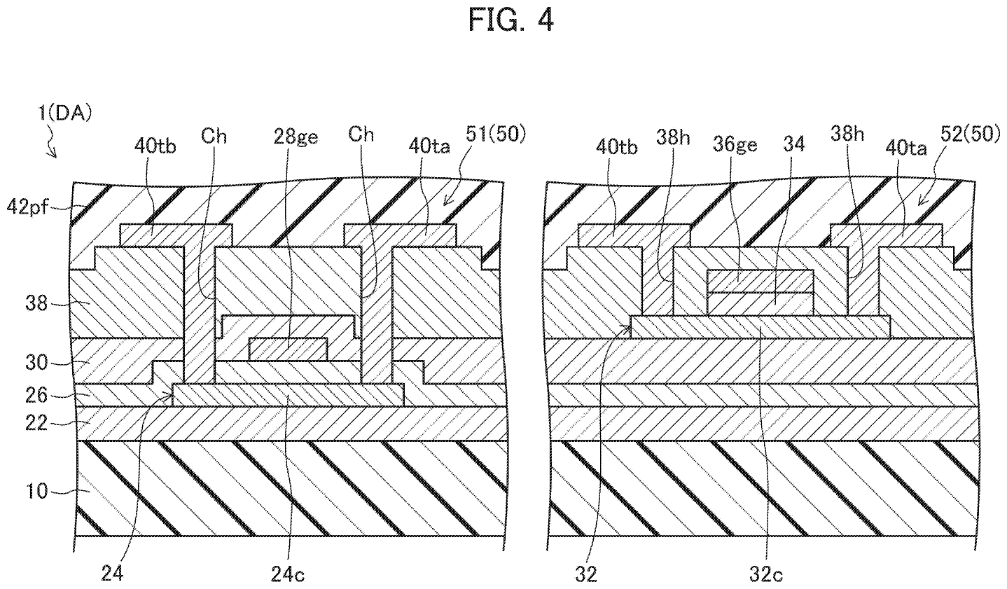

The TFT layer 20 includes a plurality of TFTs 50. As illustrated in FIG. 3 and FIG. 4, the TFT layer 20 includes the following provided sequentially on the substrate layer 10: a base coat film 22, a first semiconductor layer 24, a first gate insulating film 26, a first conductive layer 28, a first interlayer insulating film 30, a second semiconductor layer 32, a second gate insulating film 34, a second conductive layer 36, a second interlayer insulating film 38, a third conductive layer 40, and a first resin layer 42.

The base coat film 22 is provided substantially all over the surface of the substrate layer 10. The first semiconductor layer 24 is provided in the form of a plurality of islands on the base coat film 22. The first semiconductor layer 24 may be provided in continuity. The first gate insulating film 26 is provided in continuity on the base coat film 22 so as to cover the plurality of first semiconductor layers 24. The first gate insulating film 26 may be provided in the form of an island on each first semiconductor layer 24.

The first conductive layer 28 is provided on the first gate insulating film 26. The first conductive layer 28 includes a plurality of gate wires 28gl, a plurality of emission control wires 28el, a plurality of lower routed wires 28hl, a plurality of first gate electrodes 28ge, and a plurality of first capacitive electrodes 28ce. These various wires and electrodes are formed in the same layer using the same material.

The first interlayer insulating film 30 is an insulator interposed between the first conductive layer 28 and the second conductive layer 36. The first interlayer insulating film 30 is provided on the first gate insulating film 26 so as to cover the plurality of gate wires 28gl, the plurality of emission control wires 28el, the plurality of lower routed wires 28hl, the plurality of first gate electrodes 28ge, and the plurality of first capacitive electrodes 28ce.

The second semiconductor layer 32 is provided in the form of a plurality of islands on the first interlayer insulating film 30. The second semiconductor layer 32 may be provided in continuity. The second gate insulating film 34 is provided in the form of an island on each second semiconductor layer 32. The second gate insulating film 34 may be provided in continuity so as to cover the plurality of second semiconductor layers 32 in common.

The second conductive layer 36 is provided on the first interlayer insulating film 30. The second conductive layer 36 includes a plurality of first power supply wires 36pl, a plurality of initialization wires 36il, a plurality of second gate electrodes 36ge, and a plurality of second capacitive electrodes 36ce. The first power supply wires 36pl, the initialization wires 36il, the second gate electrodes 36ge, and the second capacitive electrodes 36ce are formed in the same layer using the same material.

The second interlayer insulating film 38 is an insulator interposed between the second conductive layer 36 and the third conductive layer 40. The second interlayer insulating film 38 is provided on the first interlayer insulating film 30 so as to cover the plurality of first power supply wires 36pl, the plurality of second gate electrodes 36ge, and the plurality of second capacitive electrodes 36ce. The first interlayer insulating film 30 and the second interlayer insulating film 38 constitute an interlayer insulating film 39. The interlayer insulating film 39 is an insulator interposed between the first conductive layer 28 and the third conductive layer 40.

The third conductive layer 40 is provided on the second interlayer insulating film 38. The third conductive layer 40 includes a plurality of source wires 40s1, a plurality of second power supply wires 40pl, a plurality of upper routed wires 40h1, the first frame wire 40fa, the second frame wire 40fb, a plurality of first terminal electrodes 40ta, and a plurality of second terminal electrodes 40tb. These various wires and electrodes are formed in the same layer using the same material.

The first resin layer 42 is provided on the second interlayer insulating film 38. The first resin layer 42 include a flattening film 42pf The flattening film 42pf covers, in the display region DA, the various wires and electrodes included in the third conductive layer 40. The TFT layer 20 has a surface flattened by the flattening film 42pf.

The base coat film 22, the first gate insulating film 26, the first interlayer insulating film 30, the second gate insulating film 34, and the second interlayer insulating film 38 are made of an inorganic insulating material, such as, for instance, silicon oxide, silicon nitride, or silicon nitride oxide. The base coat film 22, the first gate insulating film 26, the first interlayer insulating film 30, the second gate insulating film 34, and the second interlayer insulating film 38 are composed of a monolayer film or laminated film made of an inorganic insulating material.

The first semiconductor layer 24 is made of polysilicon. An example of the polysilicon constituting the first semiconductor layer 24 is low-temperature polycrystalline silicon (LTPS). The second semiconductor layer 32 is made of an oxide semiconductor. An example of the oxide semiconductor constituting the second semiconductor layer 32 is an In—Ga—Zn—O semiconductor.

The In—Ga—Zn—O semiconductor is a ternary oxide of indium (In), gallium (Ga), and zinc (Zn) and may contain In, Ga, and Zn at any ratio (composition ratio). The In—Ga—Zn—O semiconductor may be amorphous or crystalline. Further, other kinds of oxide semiconductor may be included instead of an In—Ga—Zn—O semiconductor.

The other kinds of oxide semiconductor may include an In—Sn—Zn—O semiconductor (e.g., In₂O₃—SnO₂—ZnO, InSnZnO) for instance. Here, the In—Sn—Zn—O semiconductor is a ternary oxide of indium (In), tin (Sn), and zinc (Zn).

The other kinds of oxide semiconductor may also include an In—Al—Zn—O semiconductor, an In—Al—Sn—Zn—O semiconductor, a Zn—O semiconductor, an In—Zn—O semiconductor, a Zn—Ti—O semiconductor, a Cd—Ge—O semiconductor, a Cd—Pb—O semiconductor, cadmium oxide (CdO), a Mg—Zn—O semiconductor, and an In—Ga—Sn—O semiconductor.

The other kinds of oxide semiconductor may also include, but not limited to, an In—Ga—O semiconductor, a Zr—In—Zn—O semiconductor, a Hf—In—Zn—O semiconductor, an Al—Ga—Zn—O semiconductor, a Ga—Zn—O semiconductor, an In—Ga—Zn—Sn—O semiconductor, InGaO₃(ZnO)₅ magnesium zinc oxide (MgₓZn₁₋ₓO), and cadmium zinc oxide (CdₓZn₁₋ₓO).

The flattening film 42pf is made of an organic resin material, such as, for instance, polyimide resin or acrylic resin, or of a polysiloxane spin-on-glass (SOG) material.

The various wires and electrodes included in the first conductive layer 28, second conductive layer 36, and third conductive layer 40 are made of a metal material, such as, for instance, aluminum (Al), tungsten (W), molybdenum (Mo), tantalum (Ta), chromium (Cr), titanium (Ti), or copper (Cu). These various wires and electrodes are composed of a monolayer film or laminated film made of a metal material.

### Wires

As illustrated in FIG. 2, the plurality of gate wires 28gl are, in the display region DA, spaced from each other in a second direction Y, which is the longitudinal direction in FIG. 1, orthogonal to the first direction X and extend parallel with each other in the first direction X. The gate wires 28gl are wires that transmit a gate signal. The gate wires 28gl include a plurality of first gate wires 28gla and a plurality of second gate wires 28glb.

The first gate wires 28gla are wires that control the TFTs 50 of N-type. The second gate wires 28glb are wires that control the TFTs 50 of P-type. The first gate wires 28gla and the second gate wires 28glb are each provided in a single row of the subpixels Sp. Each first gate wire 28gla and each second gate wire 28glb are connected to the gate driver of the drive circuit Dc.

The plurality of emission control wires 28el are spaced from each other in the second direction Y in the display region DA and extend parallel with each other in the first direction X. The emission control wires 28el are wires that transmit an emission signal. The emission control wires 28el are each provided in a single row of the subpixels Sp. Each emission control wire 28el is connected to the emission driver of the drive circuit Dc.

The plurality of initialization wires 36il extend parallel with each other in the first direction X and spaced from each other in the second direction Y The initialization wires 36il are wires that supply an initialization voltage. The initialization wires 36il are each provided in a single row of the subpixels Sp. Each initialization wire 36il is connected to the drive circuit Dc.

The plurality of first power supply wires 36pl are spaced from each other in the second direction Y in the display region DA and extend parallel with each other in the first direction X.

The first power supply wires 36pl are wires that supply a predetermined high-level power-supply voltage. The first power supply wires 36pl are each provided in a single row of the subpixels Sp. Each first power supply wire 36pl is connected to the first frame wire 40fa via a contact hole (not shown) formed in the second interlayer insulating film 38.

The plurality of source wires 40sl are spaced from each other in the first direction X in the display region DA and extend parallel with each other in the second direction Y The source wires 40sl are wires that transmit a source signal. The source wires 40sl are each provided in a single row of the subpixels Sp. Each source wire 40sl is connected to the corresponding routed wire L1 and is connected to the display control circuit via the terminal section T.

The plurality of second power supply wires 40pl are spaced from each other in the first direction X in the display region DA and extend parallel with each other in the second direction Y Each second power supply wire 40pl is connected to the first frame wire 40fa. The first power supply wire 36pl and the second power supply wire 40pl constitute a power supply wire Pl. The power supply wire Pl is a wire that applies a predetermined high-level power-supply voltage (ELVDD).

The plurality of lower routed wires 28hl are spaced from each other in the first direction X in the frame region FA between the display region DA and bending section B, and in the frame region FA between the bending section B and terminal section T, and the plurality of lower routed wires 28hl extend parallel with each other in the second direction Y Each lower routed wire 28hl located closer to the display region DA than the bending section B is connected to the corresponding source wire 40sl via a contact hole (not shown) formed in the interlayer insulating film 39.

The plurality of upper routed wires 40hl extend parallel with each other in the second direction Y so as to stride the bending section B, and the plurality of upper routed wires 40hl are spaced from each other in the first direction X. Each upper routed wire 40hl is connected to the lower routed wire 28hl located closer to the display region DA than the bending section B via a contact hole (not shown) formed in the interlayer insulating film 39, and to the lower routed wire 28hl located closer to the terminal section T than the bending section B via a contact hole (not shown) formed in the interlayer insulating film 39.

Electrodes, TFTs, and Capacitor The plurality of first gate electrodes 28ge, the plurality of second gate electrodes 36ge, the plurality of first terminal electrodes 40ta, and the plurality of second terminal electrodes 40tb are provided for each subpixel Sp. As illustrated in FIG. 4, the first gate electrode 28ge, the first terminal electrode 40ta, and the second terminal electrode 40tb constitute a TFT 50, and the second gate electrode 36ge, the first terminal electrode 40ta, and the second terminal electrode 40tb constitute a TFT 50.

The plurality of TFTs 50 are provided in each subpixel Sp. The plurality of TFTs 50 provided in each subpixel Sp include a first TFT 51 and a second TFT 52. In this example, the first TFT 51 and the second TFT 52 are both TFTs 50 of single-gate structure. The first TFT 51 and the second TFT 52 are each configured as a top-gate type.

The first TFT 51 has the first semiconductor layer 24, the first gate insulating film 26, the first gate electrode 28ge, the interlayer insulating film 39, the first terminal electrode 40ta, and the second terminal electrode 40tb. The first gate electrode 28ge overlaps the first semiconductor layer 24 with the first gate insulating film 26 interposed therebetween. The first terminal electrode 40ta and second terminal electrode 40tb of the first TFT 51 are separated from each other and are positioned so as to sandwich the first gate electrode 28ge in plan view.

The first terminal electrode 40ta and second terminal electrode 40tb of the first TFT 51 are individually connected to mutually different parts (conduction regions) of the first semiconductor layer 24 sandwiching a region (intrinsic region) overlapping the first gate electrode 28ge, via contact holes Ch formed in the first gate insulating film 26 and interlayer insulating film 39. The region of the first semiconductor layer 24 between the part connected to the first terminal electrode 40ta and the part connected to the second terminal electrode 40tb constitutes a channel region 24c.

The second TFT 52 has the second semiconductor layer 32, the second gate insulating film 34, the second gate electrode 36ge, the second interlayer insulating film 38, the first terminal electrode 40ta, and the second terminal electrode 40tb. The second gate electrode 36ge overlaps the second semiconductor layer 32 with the second gate insulating film 34 interposed therebetween. The first terminal electrode 40ta and second terminal electrode 40tb of the second TFT 52 are separated from each other and are positioned so as to sandwich the second gate electrode 36ge in plan view.

The first terminal electrode 40ta and second terminal electrode 40tb of the second TFT 52 are individually connected to mutually different parts (conduction regions) of the second semiconductor layer 32 sandwiching a region (intrinsic region) overlapping the second gate electrode 36ge, via contact holes 38h formed in the second interlayer insulating film 38. The region of the second semiconductor layer 32 between the part connected to the first terminal electrode 40ta and the part connected to the second terminal electrode 40tb constitutes a channel region 32c.

As illustrated in FIG. 3, each first capacitive electrode 28ce and each second capacitive electrode 36ce are provided for a single subpixel Sp. The first capacitive electrode 28ce and the second capacitive electrode 36ce constitute a capacitor 55. At least one capacitor 55 is provided for each subpixel Sp. The capacitor 55 is an element for data retention. The capacitor 55 is composed of the first capacitive electrode 28ce, the first interlayer insulating film 30, and the second capacitive electrode 36ce. The first capacitive electrode 28ce and the second capacitive electrode 36ce overlap each other with the first interlayer insulating film 30 interposed therebetween.

### Light-Emitting Element Layer

The light-emitting element layer 60 is provided on the TFT layer 20. The light-emitting element layer 60 includes a plurality of organic EL elements (organic electroluminescence elements) 70. The organic EL elements 70 are example light-emitting elements. The light-emitting element layer 60 includes the following provided sequentially on the first resin layer 42: a fourth conductive layer 62, a second resin layer 64, an organic EL layer 66, and a fifth conductive layer 68.

The fourth conductive layer 62 includes a plurality of pixel electrodes 62pe. Each pixel electrode 62pe is provided for a single subpixel Sp in the display region DA. The pixel electrodes 62pe function as anodes that inject positive holes (holes) into the organic EL layer 66. The pixel electrodes 62pe have the property of reflecting light (light reflectivity). The pixel electrodes 62pe are preferably made of a material having a large work function.

Examples of the material of the pixel electrodes 62pe include metals, such as silver (Ag), aluminum (Al), nickel (Ni), titanium (Ti), indium (In), and tin (Sn). The material of the pixel electrodes 62pe may be a metal compound or an alloy. The material of the pixel electrodes 62pe may be a conductive oxide, such as tin oxide (SnO) or zinc oxide (ZnO). The pixel electrodes 62pe may be formed by stacking a plurality of layers made of a conductive material.

The second resin layer 64 includes an edge cover 64ec and photo-spacers 64ps. These edge cover 64ec and photo-spacers 64ps are formed in the same layer using the same material. The edge cover 64ec and the photo-spacers 64ps are made of, but not limited to, an organic resin material, such as polyimide resin or acrylic resin for instance, or a polysiloxane SOG material.

The edge cover 64ec sections the pixel electrodes 62pe adjacent to each other. The edge cover 64ec is formed in the form of a lattice as a whole and covers the edge of each pixel electrode 62pe. The edge cover 64ec has openings 64eo from which the respective pixel electrodes 62pe are exposed. Part of the surface of the edge cover 64ec constitutes a plurality of photo-spacers 64ps.

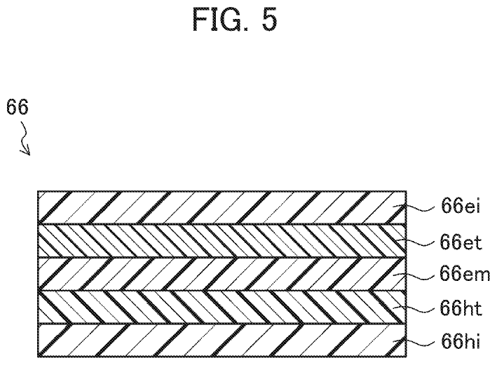

The organic EL layer 66 is an example light-emission function layer. The organic EL layer 66 is provided on each pixel electrode 62pe within the corresponding opening 64eo of the edge cover 64ec. As illustrated in FIG. 5, the organic EL layer 66 has the following sequentially provided on the pixel electrode 62pe: a hole injection layer 66hi, a hole transport layer 66ht, a light-emitting layer 66em, an electron transport layer 66et, and an electron injection layer 66ei. Some of these function layers may be shared among the plurality of subpixels Sp as continual layers.

The hole injection layer 66hi is also called an anode buffer layer. The hole injection layer 66hi improves the efficiency of hole injection from the pixel electrode 62pe into the organic EL layer 66. As the material of the hole injection layer 66hi, a well-known compound is used that matches the work function of the pixel electrode 62pe and the molecular orbital of the hole transport layer 66ht together. Examples of such a compound that is used for the hole injection layer 66hi include a triazole derivative, an oxadiazole derivative, an imidazole derivative, and a polyarylalkane derivative.

The hole transport layer 66ht improves the efficiency of hole transport to the light-emitting layer 66em. As the material of the hole transport layer 66ht, a well-known compound is used that has a small electron affinity and high hole mobility. Examples of such a compound that is used for the hole transport layer 66ht include an aromatic amine compound, a carbazole derivative, and an anthracene derivative.

Upon current application from the pixel electrode 62pe and a common electrode 68ce, the light-emitting layer 66em recombines together a hole injected from the pixel electrode 62pe and an electron injected from the common electrode 68ce, to thus emit light. As the material of the light-emitting layer 66em, a well-known light-emitting material is used that is, for instance, suitable for the emitted-light color (red, green, or blue) of the organic EL element 70 in each subpixel Sp.

Examples of the light-emitting material that is used for the light-emitting layer 66em that emits red light include a tetracene derivative and a diamine derivative. An example of the light-emitting material that is used for the light-emitting layer 66em that emits green light is an aromatic amine derivative. Examples of the light-emitting material that is used for the light-emitting layer 66em that emits blue light include a styrylamine derivative and a perylene derivative.

The electron transport layer 66et improves the efficiency of electron transport to the light-emitting layer 66em. As the material of the electron transport layer 66et, a well-known compound is used that has a large electron affinity and high electron mobility. Examples of such a compound that is used for the electron transport layer 66et include a metal complex, an aromatic heterocyclic compound, and a high-molecular compound.

The electron injection layer 66ei is also called an anode buffer. The electron injection layer 66ei improves the efficiency of electron injection from the common electrode 68ce into the organic EL layer 66. As the material of the electron injection layer 66ei, a well-known compound is used that matches together the work function of the common electrode 68ce and the molecular orbital of the electron transport layer 66et. Examples of a compound that is used for the electron injection layer 66ei include a metal complex, an alkali metal, an alkaline-earth metal, and their compounds.

The fifth conductive layer 68 includes the common electrode 68ce. The common electrode 68ce is shared among the plurality of subpixels Sp in continuity. The common electrode 68ce is provided on the organic EL layer 66 so as to cover the edge cover 64ec, and the common electrode 68ce overlaps each pixel electrode 62pe with the organic EL layer 66 interposed therebetween. The common electrode 68ce functions a cathode that injects electrons into the organic EL layer 66. The common electrode 68ce has the property of transmitting light (light transparency). The common electrode 68ce is preferably made of a material having a small work function.

Examples of the material of the common electrode 68ce include conductive oxides, such as indium tin oxide (ITO) and indium zinc oxide (IZO). The material of the common electrode 68ce may be metals, including silver (Ag), aluminum (Al), lithium (Li), magnesium (Mg), calcium (Ca), and ytterbium (Yb). The material of the common electrode 68ce may be a metal compound or an alloy. The common electrode 68ce may be formed by stacking a plurality of layers made of a conductive material.

### Organic EL Element

Each organic EL element 70 is provided for a single subpixel Sp. The plurality of organic EL elements 70 are all configured as a top-emission type. Each organic EL element 70 has the pixel electrode 62pe, the organic EL layer 66, and the common electrode 68ce. In the organic EL element 70, the organic EL layer 66 emits light upon current application between the pixel electrode 62pe and the common electrode 68ce. The organic EL elements 70 emit light in regions corresponding to the respective openings 64eo of the edge cover 64ec.

### Sealing Film

As illustrated in FIG. 3, the sealing film 80 is provided on the light-emitting element layer 60 so as to cover the plurality of organic EL elements 70. The sealing film 80 protects the individual organic EL elements 70 (organic EL layer 66 in particular) from moisture and other things. The sealing film 80 has the following sequentially provided on the light-emitting element layer 60: a first inorganic sealing layer 82, an organic sealing layer 84, and a second inorganic sealing layer 86.

The first inorganic sealing layer 82 covers the common electrode 68ce in the display region DA and extends to the frame region FA. The second inorganic sealing layer 86 covers the organic sealing layer 84 and extends to the frame region FA. The edge of the second inorganic sealing layer 86 and the edge of the first inorganic sealing layer 82 overlap each other on the outer periphery of the frame region FA. The organic sealing layer 84 is enclosed by the first inorganic sealing layer 82 and the second inorganic sealing layer 86.

The first inorganic sealing layer 82 and the second inorganic sealing layer 86 are each made of an inorganic insulating material, such as, for instance, silicon oxide, silicon nitride, or silicon nitride oxide. The organic sealing layer 84 is made of an organic resin material, such as, for instance, acrylic resin, epoxy resin, silicone resin, polyurea resin, parylene resin, polyimide resin, or polyamide resin.

### Pixel Circuit

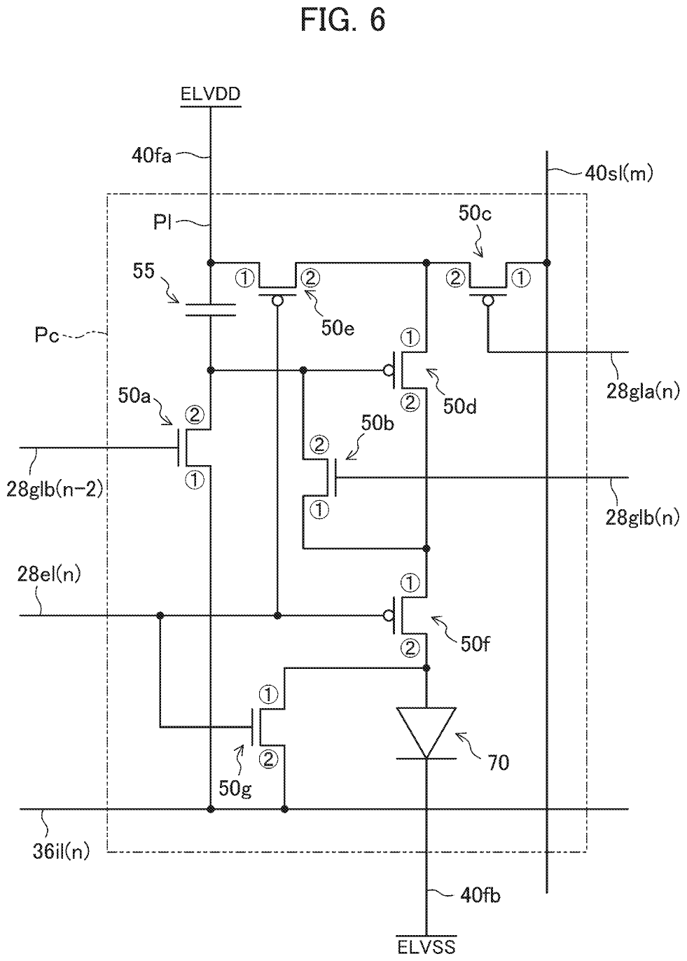

The plurality of TFTs 50, capacitor 55 and organic EL element 70 provided in each subpixel Sp constitute a pixel circuit Pc as illustrated in FIG. 6. The pixel circuit Pc controls the light emission from the organic EL element 70 on the basis of a gate signal, an emission signal, a source signal, an initialization voltage, a high-level power-supply voltage, and a low-level power-supply voltage, all of which are supplied from the various wires.

The pixel circuit Pc illustrated in FIG. 6 is the pixel circuit Pc of the subpixel Sp in the m-th row and the n-th column (where m and n are positive integers). In the equivalent-circuit diagram of FIG. 6, the first terminal electrodes 40ta of the TFTs 50 are denoted by a circled figure and the number 1, and the second terminal electrodes 40tb of the TFTs 50 are denoted by a circled figure and the number 2. In FIG. 6, the source wire 40sl with the reference sign (m) is the m-stage source wire 40sl corresponding to the subpixel Sp in the m-th row.

In FIG. 6, the first gate wire 28gla, second gate wire 28glb, emission control wire 28el, and initialization wire 36il with the reference sign (n) are respectively the n-stage first gate wire 28gla, second gate wire 28glb, emission control wire 28el, and initialization wire 36il corresponding to the subpixel Sp in the n-th column. Further, in FIG. 6, the second gate wire 28glb with the reference sign (n-2) is the n-2-stage second gate wire 28glb that undergoes scanning two stages earlier than the n-stage second gate wire 28glb.

The plurality of TFTs 50 constituting the pixel circuit Pc are an initialization TFT 50a, a compensation TFT 50b, a write TFT 50c, a drive TFT 50d, a power supply TFT 50e, an emission control TFT 50f, and an anode discharge TFT 50g. The write TFT 50c, the drive TFT 50d, the power supply TFT 50e, and the emission control TFT 50f are each a P-type channel TFT 50. The initialization TFT 50a, the compensation TFT 50b, and the anode discharge TFT 50g are each an N-type channel TFT 50.

The initialization TFT 50a is provided between the second gate wire 28glb(n-2), which is in the last stage but one (n-2 stage), the initialization wire 36il(n), which is in the target stage (n-stage), and the capacitor 55 in each subpixel Sp. The second gate electrode 36ge of the initialization TFT 50a is connected to the second gate wire 28glb(n-2). The first terminal electrode 40ta of the initialization TFT 50a is connected to the initialization wire 36il(n). The second terminal electrode 40tb of the initialization TFT 50a is connected to the first capacitive electrode 28ce of the capacitor 55.

The compensation TFT 50b is provided between the second gate wire 28glb(n), which is in the target stage (n-stage), and the drive TFT 50d in each subpixel Sp. The second gate electrode 36ge of the compensation TFT 50b is connected to the second gate wire 28glb(n). The first terminal electrode 40ta of the compensation TFT 50b is connected to the second terminal electrode 40tb of the drive TFT 50d. The second terminal electrode 40tb of the compensation TFT 50b is connected to the first gate electrode 28ge of the drive TFT 50d.

The write TFT 50c is provided between the first gate wire 28gla(n), which is in the target stage (n-stage), the source wire 40sl(m), which is in the target stage (m-stage), and the drive TFT 50d in each subpixel Sp. The first gate electrode 28ge of the write TFT 50c is connected to the first gate wire 28gla(n). The first terminal electrode 40ta of the write TFT 50c is connected to the source wire 40sl(m). The second terminal electrode 40tb of the write TFT 50c is connected to the first terminal electrode 40ta of the drive TFT 50d.

The drive TFT 50d is provided between the initialization TFT 50a, the compensation TFT 50b, the capacitor 55, the write TFT 50c, the power supply TFT 50e, and the emission control TFT 50f in each subpixel Sp. The first gate electrode 28ge of the drive TFT 50d is connected to the second terminal electrode 40tb of the compensation TFT 50b, and the second terminal electrode 40tb of the initialization TFT 50a. The first terminal electrode 40ta of the drive TFT 50d is connected to the second terminal electrode 40tb of the write TFT 50c, and the second terminal electrode 40tb of the power supply TFT 50e. The second terminal electrode 40tb of the drive TFT 50d is connected to the first terminal electrode 40ta of the compensation TFT 50b, and the first terminal electrode 40ta of the emission control TFT 50f.

The power supply TFT 50e is provided between the emission control wire 28el(n), which is in the target stage (n-stage), the power supply wire Pl, and the drive TFT 50d in each subpixel Sp. The first gate electrode 28ge of the power supply TFT 50e is connected to the emission control wire 28el(n). The first terminal electrode 40ta of the power supply TFT 50e is connected to the power supply wire Pl. The second terminal electrode 40tb of the power supply TFT 50e is connected to the first terminal electrode 40ta of the drive TFT 50d.

The emission control TFT 50f is provided between the emission control wire 28el(n), which is in the target stage (n-stage), the drive TFT 50d, and the organic EL element 70 in each subpixel Sp. The first gate electrode 28ge of the emission control TFT 50f is connected to the emission control wire 28el(n). The first terminal electrode 40ta of the emission control TFT 50f is connected to the second terminal electrode 40tb of the drive TFT 50d. The second terminal electrode 40tb of the emission control TFT 50f is connected to the pixel electrode 62pe of the organic EL element 70.

The anode discharge TFT 50g is provided between the emission control wire 28el(n), which is in the target stage (n-stage), the initialization wire 36il(n), which is in the target stage (n-stage), and the organic EL element 70. The first gate electrode 28ge of the anode discharge TFT 50g is connected to the emission control wire 28el(n). The first terminal electrode 40ta of the anode discharge TFT 50g is connected to the pixel electrode 62pe of the organic EL element 70. The second terminal electrode 40tb of the anode discharge TFT 50g is connected to the initialization wire 36il(n).

The capacitor 55 is provided between the power supply wire Pl, the initialization TFT 50a, and the drive TFT 50d. The first capacitive electrode 28ce of the capacitor 55 is connected to the first gate electrode 28ge of the drive TFT 50d, the second terminal electrode 40tb of the initialization TFT 50a, and the second terminal electrode 40tb of the compensation TFT 50b. The second capacitive electrode 36ce of the capacitor 55 is connected to the power supply wire Pl.

### TFT's Channel Length and Channel Width

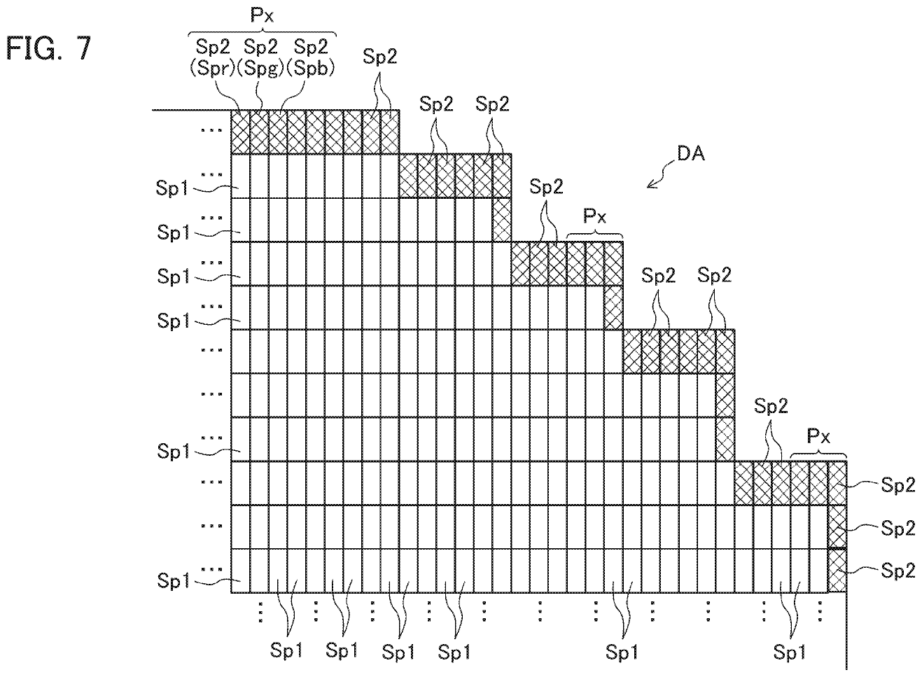

As illustrated in FIG. 7, the plurality of subpixels Sp constituting the display region DA include first subpixels Sp1 (subpixels Sp without a hatch pattern in FIG. 7) and second subpixels Sp2 (subpixels Sp with a hatch pattern in FIG. 7).

The first subpixels Sp1 are subpixels Sp located closer to the middle of the display region DA than the second subpixels Sp2. The four sides of each first subpixel Sp1 are adjacent to other subpixels Sp. Among the plurality of subpixels Sp constituting the display region DA, subpixels Sp excluding the second subpixels Sp2 are the first subpixels Sp1. The second subpixels Sp2 are subpixels Sp located at the outer edge of the display region DA. Two or three of the sides of each second subpixel Sp2 are adjacent to other subpixels Sp.

In each subpixel Sp, the write TFT 50c, the drive TFT 50d, the power supply TFT 50e, and the emission control TFT 50f are each provided as the first TFT 51 having the first semiconductor layer 24. In each subpixel Sp, the initialization TFT 50a, the compensation TFT 50b, and the anode discharge TFT 50g are each provided as the second TFT 52 having the second semiconductor layer 32.

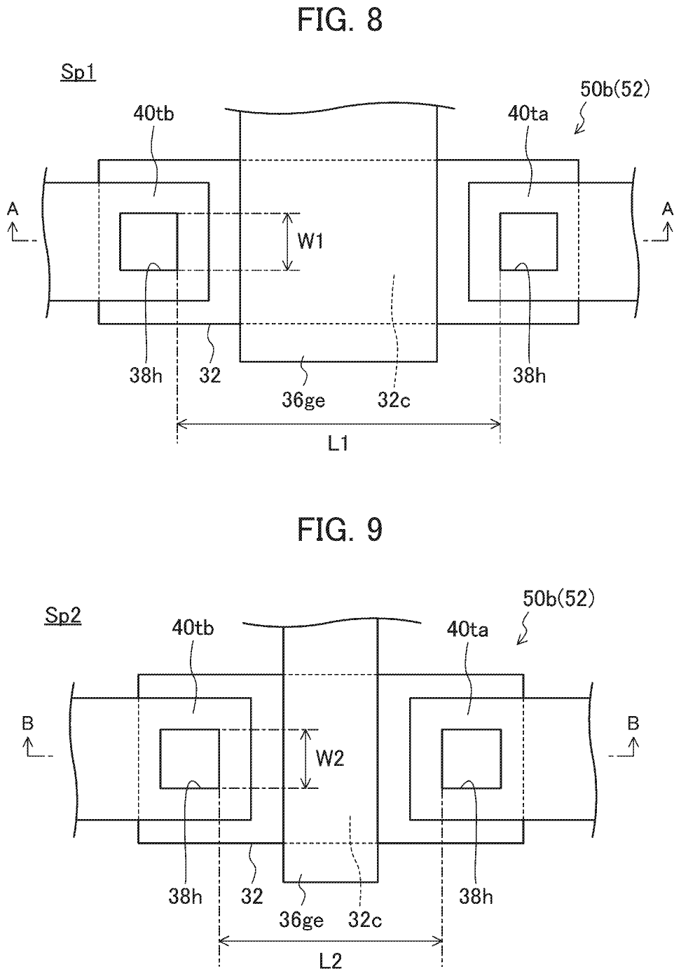

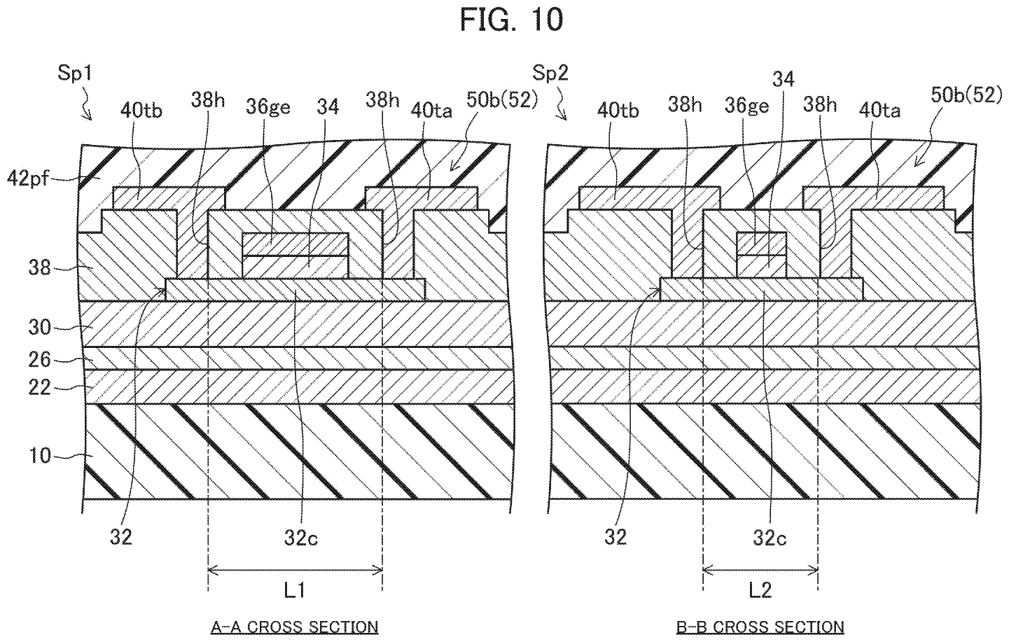

Among the plurality of TFTs 50 provided in the second subpixel Sp2, the compensation TFT 50b is designed so as to be able to obtain a higher ON current than the compensation TFT 50b provided in the first subpixel Sp1. In this example, a channel length L1 of the compensation TFT 50b of the first subpixel Sp1 and a channel length L2 of the compensation TFT 50b of the second subpixel Sp2 are different from each other, as illustrated in FIG. 8 and FIG. 9.

To be specific, the channel length L2 of the compensation TFT 50b of the second subpixel Sp2 is shorter than the channel length L1 of the compensation TFT 50b of the first subpixel Sp1. On the other hand, a channel width W1 of the compensation TFT 50b of the first subpixel Sp1 and a channel width W2 of the compensation TFT 50b of the second subpixel Sp2 having an identical function are equal to each other. Here, the channel length L1 or L2 is the distance between the part of the channel region 32c of the second semiconductor layer 32 where the first terminal electrode 40ta is connected, and the part of the same where the second terminal electrode 40tb is connected. The channel width W1 or W2 is the length of the channel region 32c of the second semiconductor layer 32 in a direction orthogonal to the direction of the channel length L2.

In the first subpixel Sp1 and the second subpixel Sp2, the channel lengths L1 and L2 of the TFTs 50 excluding the compensation TFT 50b are equal to each other between the TFTs 50 having an identical function, and the channel widths W1 and W2 of the TFTs 50 excluding the compensation TFT 50b are equal to each other between the TFTs 50 having an identical function.

That is, the channel length L1 of the initialization TFT 50a of the first subpixel Sp1 and the channel length L2 of the initialization TFT 50a of the second subpixel Sp2 are equal to each other, and the channel width W1 of the initialization TFT 50a of the first subpixel Sp1 and the channel width W2 of the initialization TFT 50a of the second subpixel Sp2 are equal to each other. The channel length L1 of the write TFT 50c of the first subpixel Sp1 and the channel length L2 of the write TFT 50c of the second subpixel Sp2 are equal to each other, and the channel width W1 of the write TFT 50c of the first subpixel Sp1 and the channel width W2 of the write TFT 50c of the second subpixel Sp2 are equal to each other.

The channel length L1 of the drive TFT 50d of the first subpixel Sp1 and the channel length L2 of the drive TFT 50d of the second subpixel Sp2 are equal to each other, and the channel width W1 of the drive TFT 50d of the first subpixel Sp1 and the channel width W2 of the drive TFT 50d of the second subpixel Sp2 are equal to each other. The channel length L1 of the power supply TFT 50e of the first subpixel Sp1 and the channel length L2 of the power supply TFT 50e of the second subpixel Sp2 are equal to each other, and the channel width W1 of the power supply TFT 50e of the first subpixel Sp1 and the channel width W2 of the power supply TFT 50e of the second subpixel Sp2 are equal to each other.

The channel length L1 of the emission control TFT 50f of the first subpixel Sp1 and the channel length L2 of the emission control TFT 50f of the second subpixel Sp2 are equal to each other, and the channel width W1 of the emission control TFT 50f of the first subpixel Sp1 and the channel width W2 of the emission control TFT 50f of the second subpixel Sp2 are equal to each other. The channel length L1 of the anode discharge TFT 50g of the first subpixel Sp1 and the channel length L2 of the anode discharge TFT 50g of the second subpixel Sp2 are equal to each other, and the channel width W1 of the anode discharge TFT 50g of the first subpixel Sp1 and the channel width W2 of the anode discharge TFT 50g of the second subpixel Sp2 are equal to each other.

### Operation of Organic EL Display

In the organic EL display 1, the corresponding emission control wire 28el in each subpixel Sp is selected to be activated (High level). Upon the emission control wire 28el being activated, the power supply TFT 50e and the emission control TFT 50f are turned off, thus bringing the organic EL element 70 into non-light emission.

In addition, upon the emission control wire 28el being activated, the anode discharge TFT 50g is turned on. Upon the anode discharge TFT 50g being turned on, a voltage of the initialization wire 36il is applied to the pixel electrode 62pe of the organic EL element 70. Accordingly, the electric charges accumulated in the pixel electrode 62pe are reset.

Next, the second gate wire 28glb in the last stage but one, which undergoes scanning two stages earlier than a second gate wire 24glb corresponding to the non-light-emission organic EL element 70, is selected to be activated (High level). Upon the second gate wire 28glb in the last stage but one being activated, a gate signal is input to the initialization TFT 50a via the second gate wire 24glb.

Upon receiving the gate signal, the initialization TFT 50a is turned on. Upon the initialization TFT 50a being turned on, a voltage (initialization voltage) of the initialization wire 36il is applied to the capacitor 55. Accordingly, the electric charges within the capacitor 55 are discharged, to thus initialize the voltage applied to the first gate electrode 28ge of the drive TFT 50d.

Next, the first gate wire 28gla corresponding to the non-light-emission organic EL element 70 is selected to be activated (High level). Upon the first gate wire 28gla being activated, the compensation TFT 50b is turned on. Then, the second gate wire 28glb corresponding to the non-light-emission organic EL element 70 is selected to be inactivated (Low level), thus turning on the write TFT 50c.

Upon the compensation TFT 50b and write TFT 50c being turned on, the drive TFT 50d is brought into diode connection, and a predetermined voltage corresponding to a source signal that is to be transmitted via the source wire 40sl is written into the capacitor 55 via the drive TFT 50d. Subsequently, the emission control wire 28el corresponding to the non-light-emission organic EL element 70 is inactivated (Low level).

Upon the emission control wire 28el being inactivated, the power supply TFT 50e and the emission control TFT 50f are turned on, and a driving current corresponding to the voltage applied to the first gate electrode 28ge of the drive TFT 50d is supplied from the power supply wire Pl to the organic EL element 70. Each organic EL element 70 emits light at a luminance level corresponding to the driving current. Accordingly, the organic EL display 1 displays an image in the display region DA.

### Method for Manufacturing Organic EL Display

To manufacture the organic EL display 1, the first process step is forming the substrate layer 10 by applying a resin material onto the surface of a glass substrate, followed by baking and other processing. The next is forming the TFT layer 20, the light-emitting element layer 60, and the sealing film 80 sequentially onto the substrate layer 10 through a well-known technique, such as photolithography, vacuum evaporation, or ink-jet printing.

The next is attaching a protective film onto the substrate surface with the sealing film 80 provided thereon. The next is removing the glass substrate from the substrate layer 10 by, for instance, irradiating the back surface of the substrate layer 10 with laser light from near the glass substrate. The next is attaching a protective film also onto the back surface of the substrate layer 10. The following is mounting the display control circuit together with the wiring board Cb by connecting the wiring board Cb to the terminal section T of this substrate. The organic EL display 1 can be manufactured through the foregoing process steps.

In the step of forming the TFT layer 20, the second semiconductor layer 32, the second gate electrode 36ge, the first terminal electrode 40ta, and the second terminal electrode 40tb are formed in such a manner that the channel length L2 of the second semiconductor layer 32 that constitutes the compensation TFT 50b of each second subpixel Sp2 is shorter than the channel length L1 of the second semiconductor layer 32 that constitutes the compensation TFT 50b of each first subpixel Sp1. By doing so, the compensation TFT 50b of the second subpixel Sp2 needs to be provided so as to be able to obtain a higher ON current than the compensation TFT 50b of the first subpixel Sp1.

### Feature of First Embodiment

In the organic EL display 1 according to the first embodiment, the channel length L2 of the compensation TFT 50b of the second subpixel Sp2 is shorter than the channel length L1 of the compensation TFT 50b of the first subpixel Sp1. The compensation TFT 50b of the second subpixel Sp2 tends to have a lower ON current property than the compensation TFT 50b of the first subpixel Sp1. If the ON current property of the compensation TFT 50b is low, a voltage that is applied to the second gate electrode 36ge of the drive TFT 50d reduces, thereby easily causing a bright spot in the corresponding second subpixel Sp2. Accordingly, setting the channel length L2 of the compensation TFT 50b of the second subpixel Sp2 to be shorter than the channel length L1 of the compensation TFT 50b of the first subpixel Sp1 can enhance the ON current property of the compensation TFT 50b of the second subpixel Sp2. This can prevent a reduction in voltage that is applied to the second gate electrode 36ge of the drive TFT 50d in the second subpixel Sp2. Consequently, the second subpixel Sp2 can be prevented from a bright spot.

### First Modification

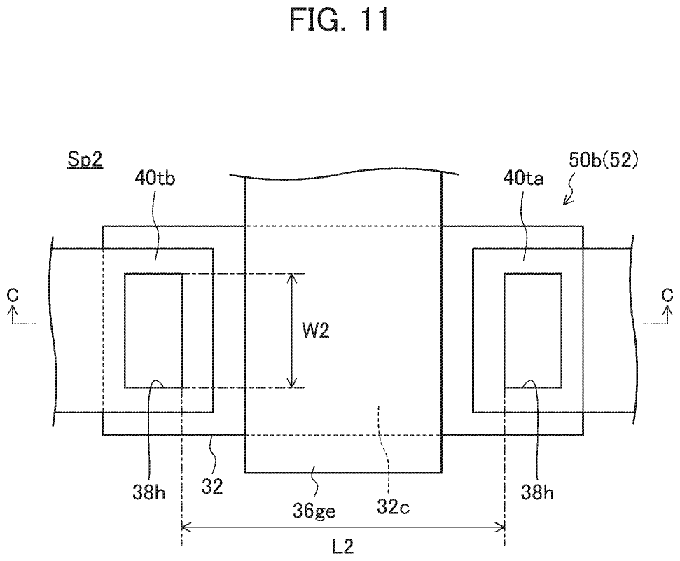

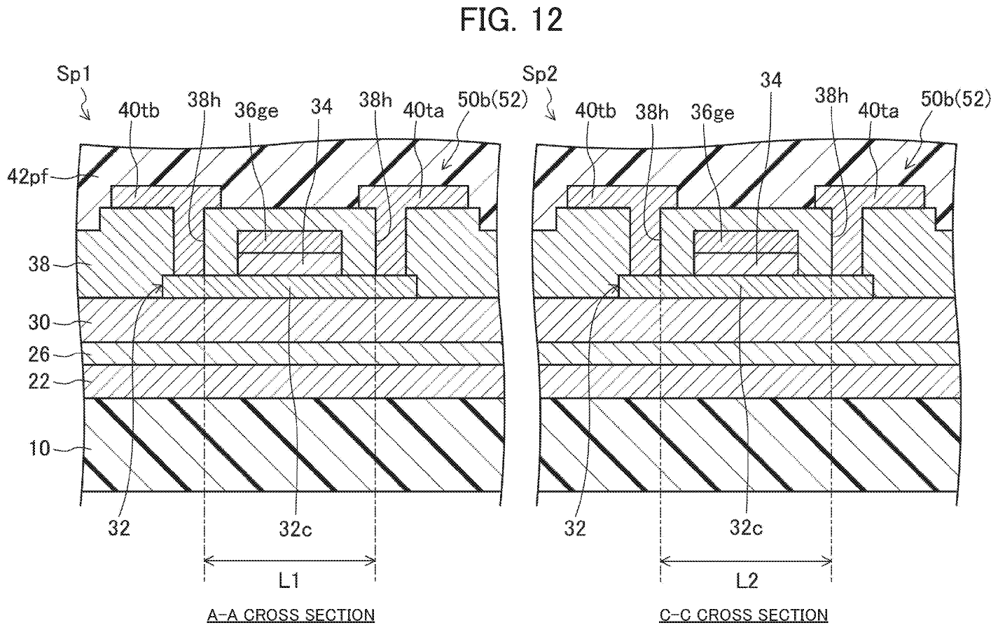

In the organic EL display 1 according to a first modification, the channel length L1 of the compensation TFT 50b of the first subpixel Sp1 and the channel length L2 of the compensation TFT 50b of the second subpixel Sp2 are equal to each other, as illustrated in FIG. 8, FIG. 11, and FIG. 12. Moreover, the channel width W1 of the compensation TFT 50b of the first subpixel Sp1 and the channel width W2 of the compensation TFT 50b of the second subpixel Sp2 are different from each other. To be specific, the channel width W2 of the compensation TFT 50b of the second subpixel Sp2 is wider than the channel width W1 of the compensation TFT 50b of the first subpixel Sp1.

### Feature of First Modification

In the organic EL display 1 according to the first modification, setting the channel width W2 of the compensation TFT 50b of the second subpixel Sp2 to be wider than the channel width W1 of the compensation TFT 50b of the first subpixel Sp1 can enhance the ON current property of the compensation TFT 50b of the second subpixel Sp2. This can prevent, like that in the first embodiment, a bright spot that is caused by a reduction in voltage that is applied to the second gate electrode 36ge of the drive TFT 50d in the second subpixel Sp2.

### Second Modification

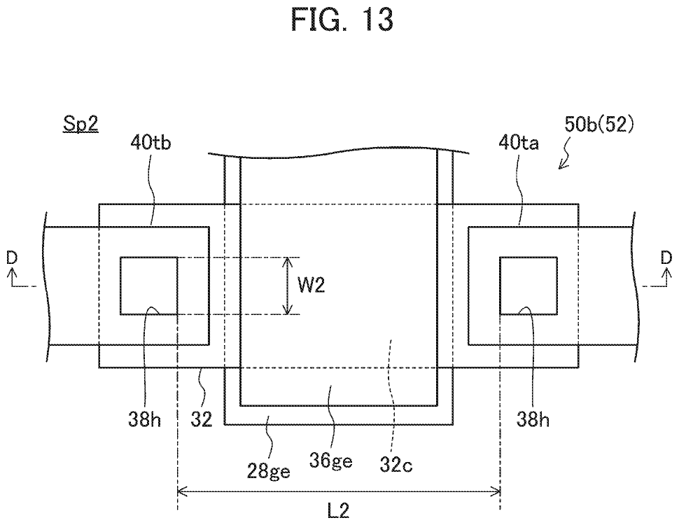

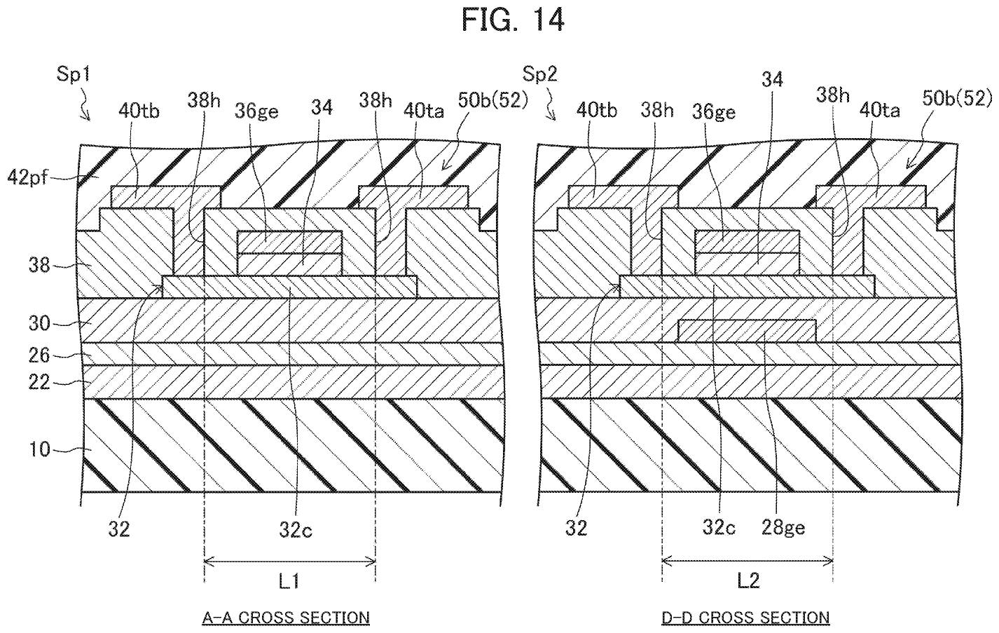

In the organic EL display 1 according to a second modification, as illustrated in FIG. 8 and FIG. 13, the channel lengths L1 and L2 of the compensation TFTs 50b are equal to each other between the first subpixel Sp1 and the second subpixel Sp2, and the channel widths W1 and W2 of the compensation TFTs 50b are equal to each other between the first subpixel Sp1 and the second subpixel Sp2. The compensation TFT 50b of the first subpixel Sp1 is, like that in the first embodiment, a TFT 50 of single-gate structure, as illustrated in FIG. 8 and the left side of FIG. 14, and the compensation TFT 50b of the second subpixel Sp2 is a TFT 50 of double-gate structure, as illustrated in FIG. 13 and the right side of FIG. 14.

The compensation TFT 50b of the second subpixel Sp2 has the first gate electrode 28ge in addition to the second gate electrode 36ge. The first gate electrode 28ge of the compensation TFT 50b is provided in a location overlapping the second semiconductor layer 32 with the first interlayer insulating film 30 interposed therebetween. The first gate electrode 28ge is connected to the same second gate wire 28glb as that connected to the second gate electrode 36ge of the compensation TFT 50b.

### Feature of Second Modification

In the organic EL display 1 according to the second modification, the first subpixel Sp1 includes the compensation TFT 50b of single-gate structure, and the second subpixel Sp2 includes the compensation TFT 50b of double-gate structure; this can relatively enhance the ON current property of the compensation TFT 50b of the second subpixel Sp2. This can prevent, like that in the first embodiment, a bright spot that is caused by a reduction in voltage that is applied to the second gate electrode 36ge of the drive TFT 50d in the second subpixel Sp2.

### Second Embodiment

The organic EL display 1 according to a second embodiment is different from that according to the first embodiment in the configuration of the compensation TFT 50b provided in the second subpixel Sp2. It is noted that the organic EL display 1 in the subsequent embodiments are configured in a manner similar to that in the first embodiment with the exception that the configuration of the compensation TFT 50b is different from that in the first embodiment. Thus, only the configuration different from that in the first embodiment will be described, and the description of the same configuration, which has been dealt with in the first embodiment, will be omitted.

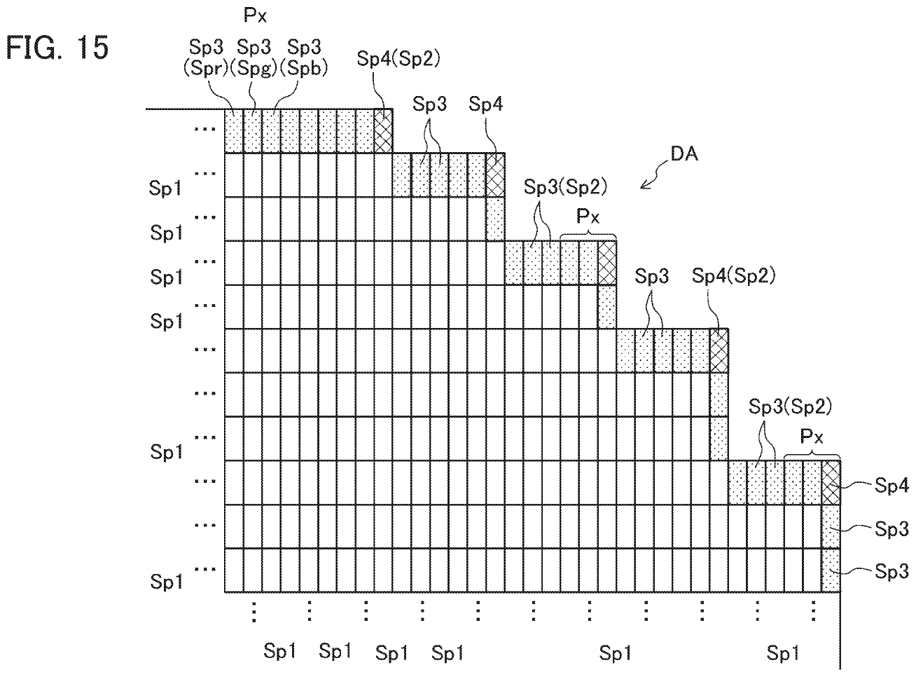

In the organic EL display 1 according to the second embodiment, not only the configuration of the compensation TFT 50b is different between the first subpixel Sp1 and the second subpixel Sp2, but also the configuration of the compensation TFT 50b is different between the second subpixels Sp2. As illustrated in FIG. 15, the plurality of second subpixels Sp2 located at the outer edge of the display region DA include third subpixels Sp3 (subpixels Sp with a dot-hatch pattern in FIG. 15), and fourth subpixels Sp4 (subpixels Sp with a lattice-hatch pattern in FIG. 15). The configuration of the compensation TFT 50b is different between the third subpixels Sp3 and the fourth subpixels Sp4.

The third subpixels Sp3 are subpixels Sp located at the outer edge but corners of the display region DA. Three of the sides of each third subpixel Sp3 are adjacent to other subpixels Sp. Among the plurality of second subpixels Sp2 located at the outer edge of the display region DA, subpixels Sp excluding the fourth subpixels Sp4 are the third subpixels Sp3. The fourth subpixels Sp4 are subpixels Sp located at the corners at the outer edge of the display region DA. Two of the sides of each fourth subpixel Sp4 are adjacent to other subpixels Sp.

The compensation TFT 50b provided in the third subpixel Sp3 is designed so as to be able to obtain a higher ON current than the compensation TFT 50b provided in the first subpixel Sp1. Moreover, the compensation TFT 50b provided in the fourth subpixel Sp4 is designed so as to be able to obtain a higher ON current than the compensation TFT 50b provided in the third subpixel Sp3.

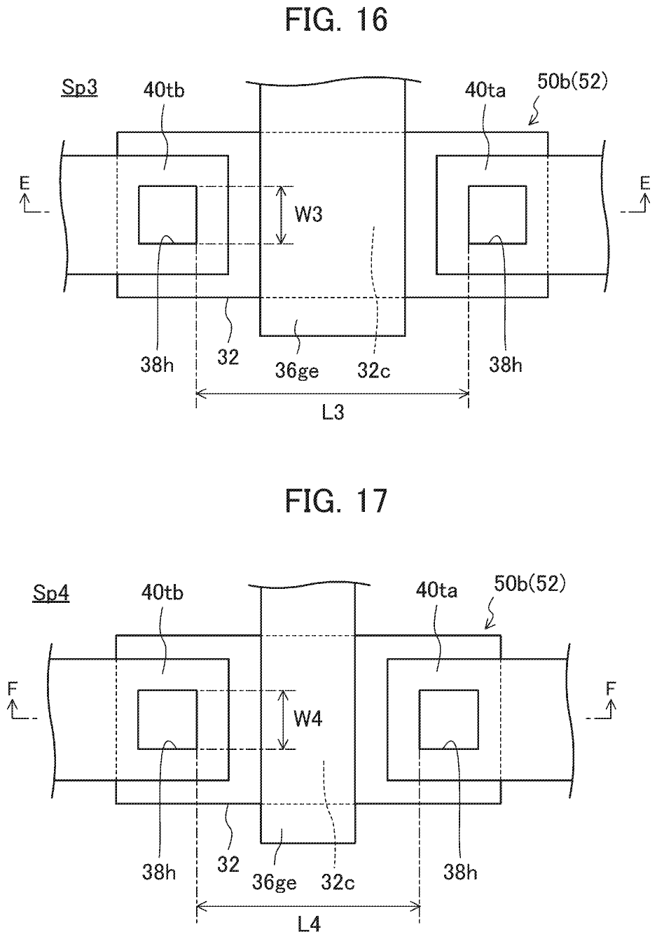

In this example, the channel width W1 of the compensation TFT 50b of the first subpixel Sp1, a channel width W3 of the compensation TFT 50b of the third subpixel Sp3, and a channel width W4 of the compensation TFT 50b of the fourth subpixel Sp4 are equal to each other, as illustrated in FIG. 8, FIG. 16, and FIG. 17.

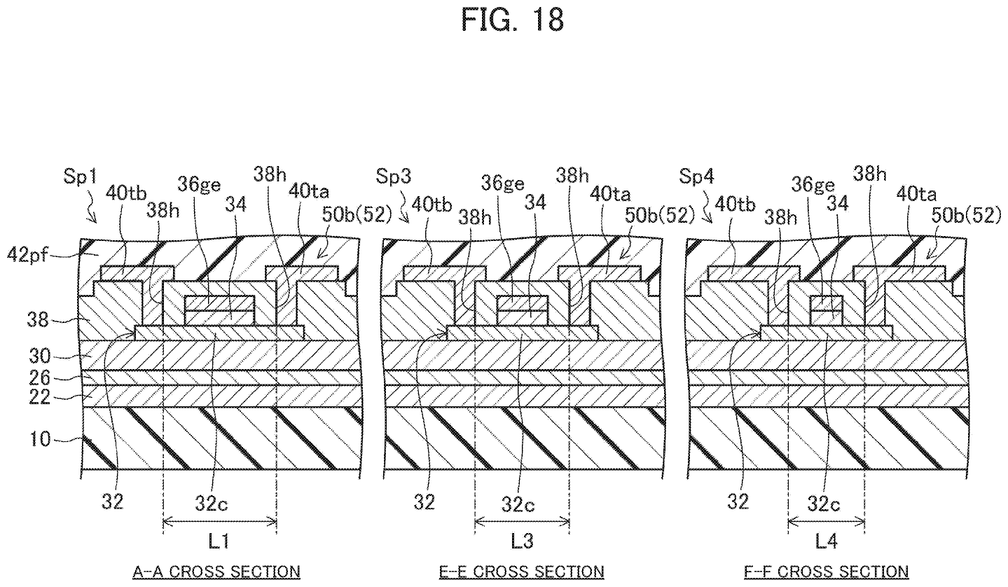

In addition, the channel length L1 of the compensation TFT 50b of the first subpixel Sp1, a channel length L3 of the compensation TFT 50b of the third subpixel Sp3, and a channel length L4 of the compensation TFT 50b of the fourth subpixel Sp4 are different from each other, as illustrated in FIG. 18. To be specific, the channel length L3 of the compensation TFT 50b of the third subpixel Sp3 is shorter than the channel length L1 of the compensation TFT 50b of the first subpixel Sp1. The channel length L4 of the compensation TFT 50b of the fourth subpixel Sp4 is shorter than the channel length L3 of the compensation TFT 50b of the third subpixel Sp3.

### Feature of Second Embodiment

In the organic EL display 1 according to the second embodiment, the channel lengths L1, L3, and L4 of the compensation TFTs 50b decrease stepwise from the first subpixel Sp1, followed by the third subpixel Sp3, followed by the fourth subpixel Sp4. The earlier described phenomenon in which the ON current property of the compensation TFT 50b of the second subpixel Sp2 is reduced, easily occurs prominently in the subpixels Sp (fourth subpixels Sp4) located at the corners of the display region DA. Accordingly, setting the channel length L4 of the compensation TFT 50b of the fourth subpixel Sp4 to be shorter than the channel length L3 of the compensation TFT 50b of the third subpixel Sp3 can enhance the ON current property of the compensation TFT 50b of the fourth subpixel Sp4 further than the ON current property of the compensation TFT 50b of the third subpixel Sp3. Consequently, the second subpixel Sp2 (the fourth subpixel Sp4 in particular) can be further prevented from a bright spot.

### Modification

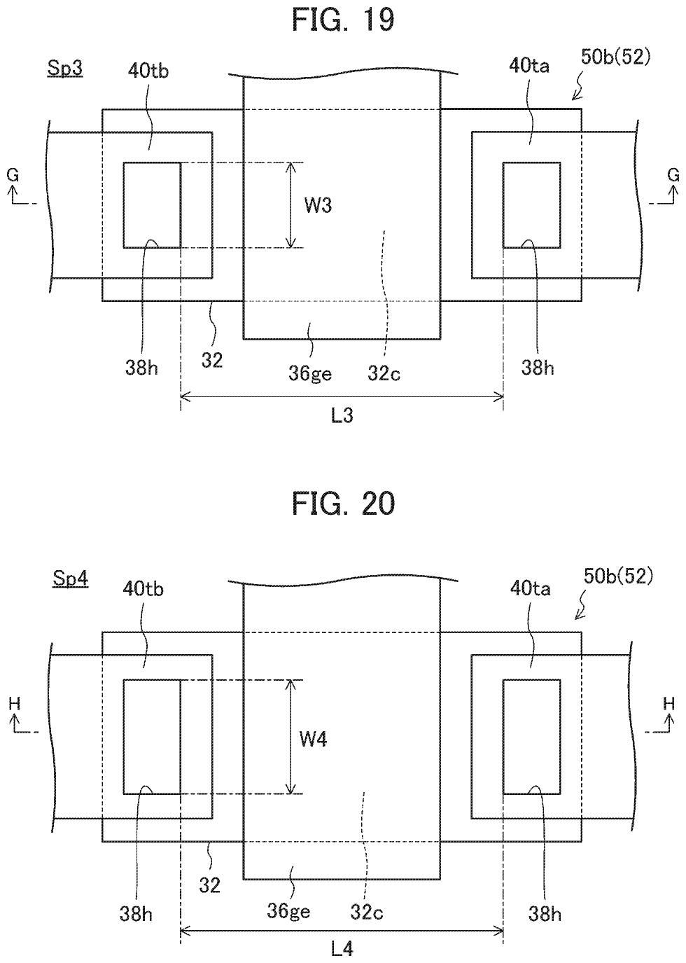

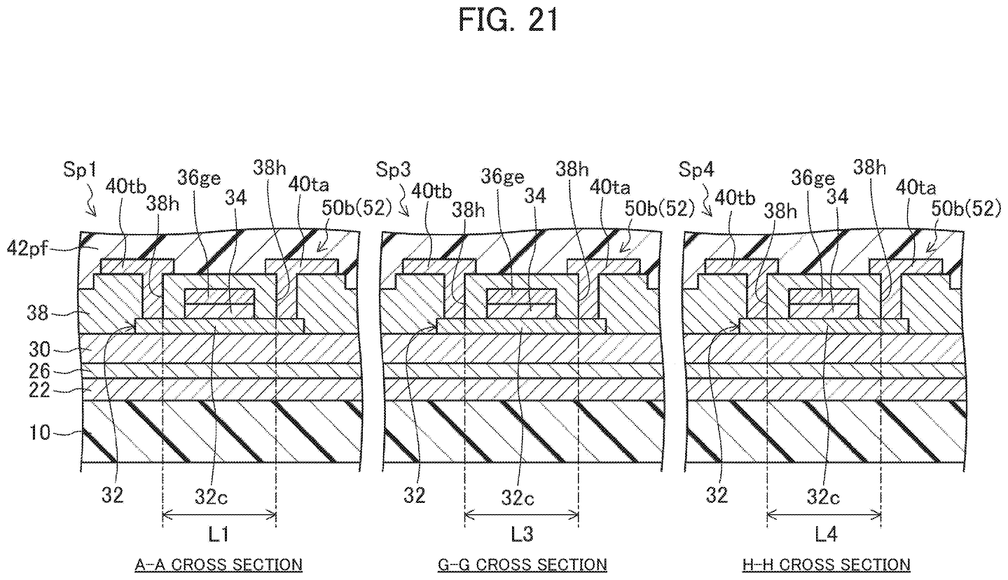

In the organic EL display 1 according to this modification, the channel length L1 of the compensation TFT 50b of the first subpixel Sp1, the channel length L3 of the compensation TFT 50b of the third subpixel Sp3, and the channel length L4 of the compensation TFT 50b of the fourth subpixel Sp4 are equal to each other, as illustrated in FIG. 8 and FIG. 19 to FIG. 21.

Moreover, the channel width W1 of the compensation TFT 50b of the first subpixel Sp1, the channel width W3 of the compensation TFT 50b of the third subpixel Sp3, and the channel width W4 of the compensation TFT 50b of the fourth subpixel Sp4 are different from each other. To be specific, the channel width W3 of the compensation TFT 50b of the third subpixel Sp3 is wider than the channel width W1 of the compensation TFT 50b of the first subpixel Sp1. The channel width W4 of the compensation TFT 50b of the fourth subpixel Sp4 is wider than the channel width W3 of the compensation TFT 50b of the third subpixel Sp3.

### Feature of Modification

In the organic EL display 1 according to this modification, the channel widths W1, W3, and W4 of the compensation TFTs 50b increase stepwise from the first subpixel Sp1, followed by the third subpixel Sp3, followed by the fourth subpixel Sp4. Setting the channel width W4 of the compensation TFT 50b of the fourth subpixel Sp4 to be wider than the channel width W3 of the compensation TFT 50b of the third subpixel Sp3 can enhance the ON current property of the compensation TFT 50b of the fourth subpixel Sp4 further than the ON current property of the compensation TFT 50b of the third subpixel Sp3. Consequently, the second subpixel Sp2 (the fourth subpixel Sp4 in particular) can be suitably prevented from a bright spot, like that in the second embodiment.

### Third Embodiment

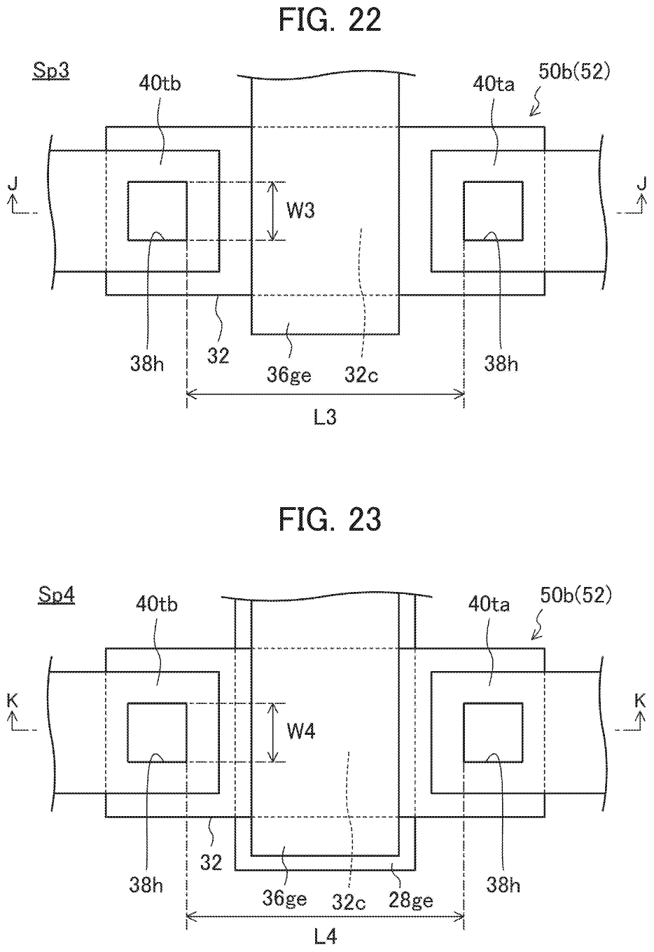

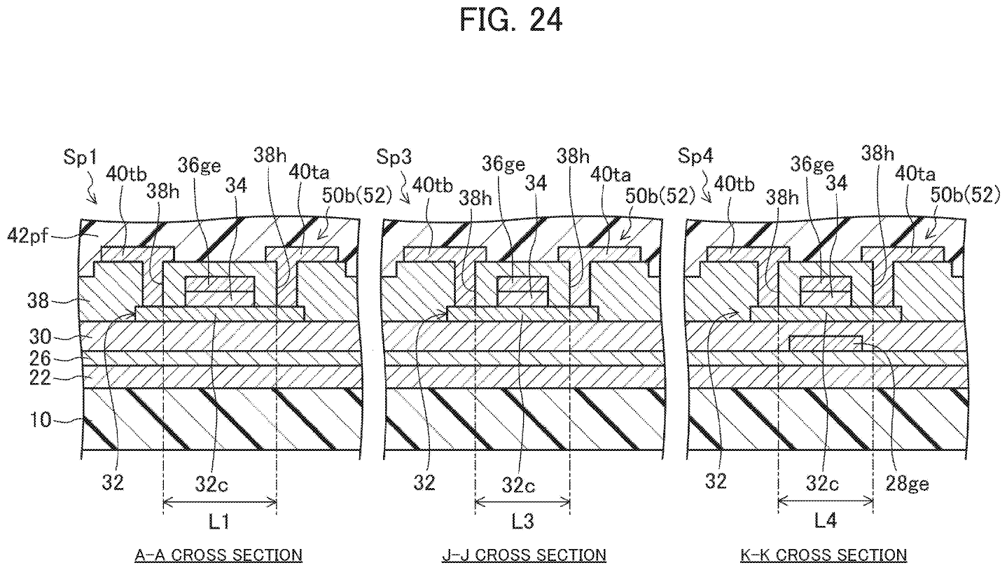

In the organic EL display 1 according to a third embodiment, not only the configuration of the compensation TFT 50b is different between the first subpixel Sp1 and the second subpixel Sp2, but also the configuration of the compensation TFT 50b is different between the third subpixel Sp3 and the fourth subpixel Sp4, which are sectioned in a manner similar to those in the second embodiment, as illustrated in FIG. 8 and FIG. 22 to FIG. 24.

In this example, the channel width W1 of the compensation TFT 50b of the first subpixel Sp1, and the channel widths W3 and W4 of the respective compensation TFTs 50b of the third subpixel Sp3 and fourth subpixel Sp4 are equal to each other. Moreover, the channel length L1 of the compensation TFT 50b of the first subpixel Sp1, and the channel lengths L3 and L4 of the respective compensation TFTs 50b of the third subpixel Sp3 and fourth subpixel Sp4 are different from each other.

To be specific, the channel length L3 of the compensation TFT 50b of the third subpixel Sp3 and the channel length L4 of the compensation TFT 50b of the fourth subpixel Sp4 are each shorter than the channel length L1 of the compensation TFT 50b of the first subpixel Sp1. The channel length L3 of the compensation TFT 50b of the third subpixel Sp3 and the channel length L4 of the compensation TFT 50b of the fourth subpixel Sp4 are equal to each other.

Further, the compensation TFT 50b of the first subpixel Sp1 and the compensation TFT 50b of the third subpixel Sp3 are TFTs 50 of single-gate structure, like those in the first embodiment. In contrast to this, the compensation TFT 50b of the fourth subpixel Sp4 is a TFT 50 of double-gate structure, like that in the second modification of the first embodiment. The compensation TFT 50b of the fourth subpixel Sp4 in this example corresponds to the compensation TFT 50b of the third subpixel Sp3 having a double-gate structure in which its channel length and channel width are equal.

### Feature of Third Embodiment

In the organic EL display 1 according to the third embodiment, the channel lengths L3 and L4 of the respective compensation TFTs 50b of the third subpixel Sp3 and fourth subpixel Sp4 are shorter than the channel length L1 of that of the first subpixel Sp1. This can enhance the ON current properties of the respective compensation TFTs 50b of the third subpixel Sp3 and fourth subpixel Sp4. Furthermore, the first subpixel Sp1 and the third subpixel Sp3 have their compensation TFTs 50b of single-gate structure, and the fourth subpixel Sp4 has its compensation TFT 50b of double-gate structure. This can enhance the ON current property of the compensation TFT 50b of the fourth subpixel Sp4 further than the ON current property of the compensation TFT 50b of the third subpixel Sp3. Consequently, the third subpixel Sp3 and the fourth subpixel Sp4 can be suitably prevented from a bright spot.

### Modification

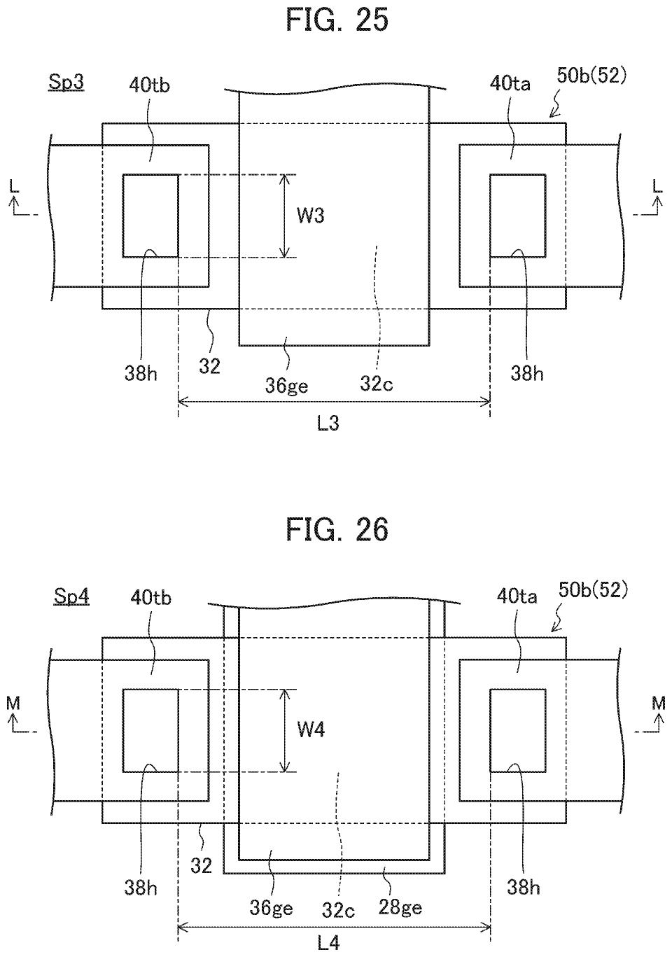

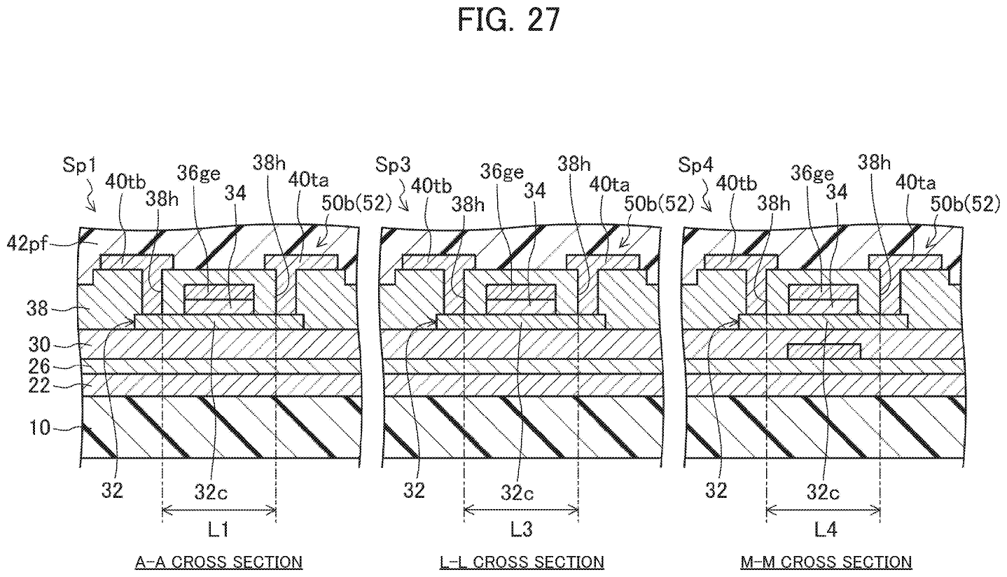

In the organic EL display 1 according to this modification, the channel length L1 of the compensation TFT 50b of the first subpixel Sp1, and the channel lengths L3 and L4 of the respective compensation TFTs 50b of the third subpixel Sp3 and fourth subpixel Sp4 are equal to each other, as illustrated in FIG. 8 and FIG. 25 to FIG. 27. Moreover, the channel width W1 of the compensation TFT 50b of the first subpixel Sp1, and the channel widths W3 and W4 of the respective compensation TFTs 50b of the third subpixel Sp3 and fourth subpixel Sp4 are different from each other.

To be specific, the channel width W3 of the compensation TFT 50b of the third subpixel Sp3 and the channel width W4 of the compensation TFT 50b of the fourth subpixel Sp4 are each wider than the channel width W1 of the compensation TFT 50b of the first subpixel Sp1. The channel width W3 of the compensation TFT 50b of the third subpixel Sp3 and the channel width W4 of the compensation TFT 50b of the fourth subpixel Sp4 are equal to each other.

Further, the compensation TFT 50b of the first subpixel Sp1 and the compensation TFT 50b of the third subpixel Sp3 are TFTs 50 of single-gate structure, like those in the first embodiment. In contrast to this, the compensation TFT 50b of the fourth subpixel Sp4 is a TFT 50 of double-gate structure, like that in the second modification of the first embodiment. The compensation TFT 50b of the fourth subpixel Sp4 in this example corresponds to the compensation TFT 50b of the third subpixel Sp3 having a double-gate structure in which its channel length and channel width are equal.

### Feature of Modification

In the organic EL display 1 according to this modification, the channel widths W3 and W4 of the respective compensation TFTs 50b of the third subpixel Sp3 and fourth subpixel Sp4 are wider than the channel width W1 of that of the first subpixel Sp1. This can enhance the ON current properties of the respective compensation TFTs 50b of the third subpixel Sp3 and fourth subpixel Sp4. Furthermore, the first subpixel Sp1 and the third subpixel Sp3 have their compensation TFTs 50b of single-gate structure, and the fourth subpixel Sp4 has its compensation TFT 50b of double-gate structure. This can enhance the ON current property of the compensation TFT 50b of the fourth subpixel Sp4 further than the ON current property of the compensation TFT 50b of the third subpixel Sp3. Consequently, the third subpixel Sp3 and the fourth subpixel Sp4 can be suitably prevented from a bright spot.

### Fourth Embodiment

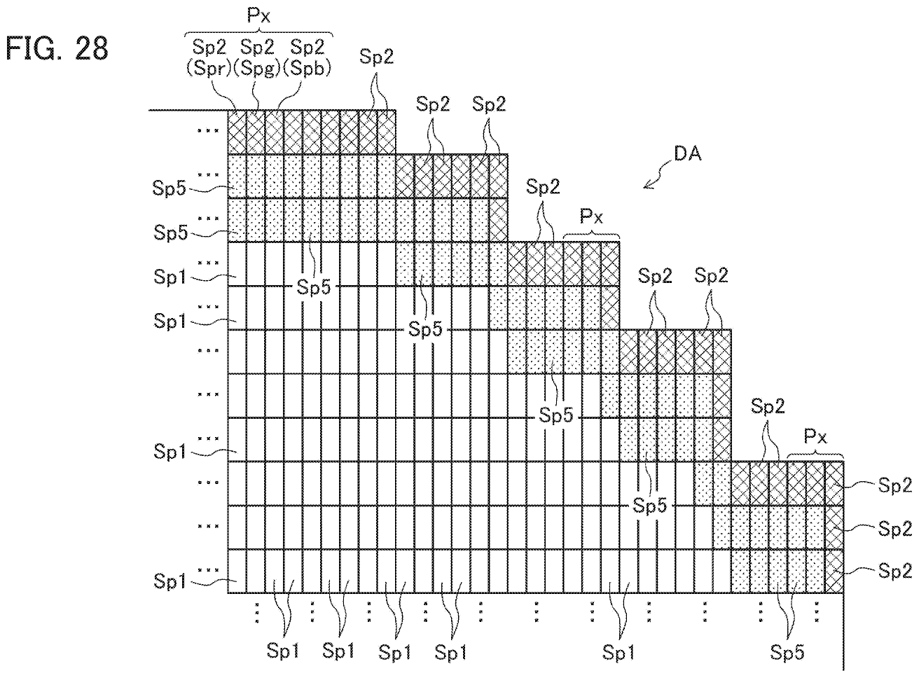

In the organic EL display 1 according to a fourth embodiment, the plurality of subpixels Sp constituting the display region DA include fifth subpixels Sp5 (subpixels Sp with a dot-hatch pattern in FIG. 28) in addition to the first subpixels Sp1 and the second subpixels Sp2, as illustrated in FIG. 28.

The fifth subpixels Sp5 are subpixels Sp located on the inner periphery of the second subpixels Sp2. Each fifth subpixel Sp5 is adjacent to the second subpixel Sp2 on at least one of its sides or is adjacent to the second subpixel Sp2 with another fifth subpixel Sp5 interposed therebetween. The magnitude relationship between the channel length L1 of the compensation TFT 50b of the first subpixel Sp1 and the channel length L2 of the compensation TFT 50b of the second subpixel Sp2 is similar to that in the first embodiment, and the magnitude relationship between the channel width W1 of the compensation TFT 50b of the first subpixel Sp1 and the channel width W2 of the compensation TFT 50b of the second subpixel Sp2 is similar to that in the first embodiment.

The channel width of the compensation TFT 50b of the fifth subpixel Sp5 is equal to the channel widths of the respective compensation TFTs 50b of the first subpixel Sp1 and second subpixel Sp2. The channel length of the compensation TFT 50b of the fifth subpixel Sp5 is shorter than the channel length L1 of the compensation TFT 50b of the first subpixel Sp1 and is longer than the channel length L2 of the compensation TFT 50b of the second subpixel Sp2. The channel lengths of the compensation TFTs 50b decrease stepwise from the first subpixel Sp1, followed by the fifth subpixel Sp5, followed by the second subpixel Sp2.

### Feature of Fourth Embodiment

In the organic EL display 1 according to the fourth embodiment, the channel lengths of the compensation TFTs 50b around the outer periphery of the display region DA decrease along with approach from the middle of the display region DA to the outer edge of the same. This can relatively enhance the ON current properties of the compensation TFTs 50b in the second subpixels Sp2 and fifth subpixels Sp5, constituting the subpixels around the outer periphery of the display region DA, and can prevent a bright spot in these subpixels.

### Modification

In the organic EL display 1 according to this modification, the magnitude relationship between the channel length L1 of the compensation TFT 50b of the first subpixel Sp1 and the channel length L2 of the compensation TFT 50b of the second subpixel Sp2 is similar to that in the first modification of the first embodiment, and the magnitude relationship between the channel width W1 of the compensation TFT 50b of the first subpixel Sp1 and the channel width W2 of the compensation TFT 50b of the second subpixel Sp2 is similar to that in the first modification of the first embodiment. The channel length of the compensation TFT 50b of the fifth subpixel Sp5 is equal to the channel lengths of the respective compensation TFTs 50b of the first subpixel Sp1 and second subpixel Sp2.

The channel width of the compensation TFT 50b of the fifth subpixel Sp5 is wider than the channel width W1 of the compensation TFT 50b of the first subpixel Sp1 and is narrower than the channel width W2 of the compensation TFT 50b of the second subpixel Sp2. The channel widths of the compensation TFTs 50b increase stepwise from the first subpixel Sp1, followed by the fifth subpixel Sp5, followed by the second subpixel Sp2.

### Feature of Modification

In the organic EL display 1 according to this modification, the channel widths of the compensation TFTs 50b around the outer periphery of the display region DA increase along with approach from the middle of the display region DA to the outer edge of the same. This can relatively enhance the ON current properties of the compensation TFTs 50b in the second subpixels Sp2 and fifth subpixels Sp5, constituting the subpixels around the outer periphery of the display region DA, and can prevent a bright spot in these subpixels.

### Other Embodiments

In the first embodiment, in addition to or instead of the compensation TFT 50b among the plurality of TFTs 50 provided in each subpixel Sp, the TFTs 50, except the compensation TFT 50b, that involve a problem, such as a bright spot, caused by a reduction in ON current property may be configured such that the channel length L2 of the TFT 50 of the second subpixel Sp2 is shorter than the channel length L1 of the TFT 50 of the first subpixel Sp1.

In the first modification of the first embodiment as well, in addition to or instead of the compensation TFT 50b among the plurality of TFTs 50 in each subpixel Sp, the TFTs 50, except the compensation TFT 50b, that involve a problem, such as a bright spot, caused by a reduction in ON current property may be configured such that the channel width W2 of the TFT 50 of the second subpixel Sp2 is wider than the channel width W1 of the TFT 50 of the first subpixel Sp1 having an identical function.

In the second modification of the first embodiment as well, in addition to or instead of the compensation TFT 50b among the plurality of TFTs 50 in each subpixel Sp, the TFTs 50 except the compensation TFT 50b may be configured such that the TFT 50 of the second subpixel Sp2 is of multi-gate structure, and such that the TFT 50 of the first subpixel Sp1 having an identical function is of single-gate structure.

In the second embodiment, in addition to or instead of the compensation TFT 50b among the plurality of TFTs 50 provided in each subpixel Sp, the TFTs 50, except the compensation TFT 50b, that involve a problem, such as a bright spot, caused by a reduction in ON current property may be configured such that the channel length L3 of the TFT 50 of the third subpixel Sp3 is shorter than the channel length L1 of the TFT 50 of the first subpixel Sp1 having an identical function, and such that the channel length L4 of the TFT 50 of the fourth subpixel Sp4 is shorter than the channel length L3 of the TFT 50 of the third subpixel Sp3 having an identical function.

In the modification of the second embodiment as well, in addition to or instead of the compensation TFT 50b among the plurality of TFTs 50 in each subpixel Sp, the TFTs 50, except the compensation TFT 50b, that involve a problem, such as a bright spot, caused by a reduction in ON current property may be configured such that the channel width W3 of the TFT 50 of the third subpixel Sp3 is wider than the channel width W1 of the TFT 50 of the first subpixel Sp1 having an identical function, and such that the channel width W4 of the TFT 50 of the fourth subpixel Sp4 is shorter than the channel width W3 of the TFT 50 of the third subpixel Sp3 having an identical function.

In the third embodiment, in addition to or instead of the compensation TFT 50b among the plurality of TFTs 50 provided in each subpixel Sp, the TFTs 50, except the compensation TFT 50b, that involve a problem, such as a bright spot, caused by a reduction in ON current property may be configured such that the channel length L3 of the TFT 50 of the third subpixel Sp3 is shorter than the channel length L1 of the TFT 50 of the first subpixel Sp1 having an identical function, such that the TFTs 50 of the first subpixel Sp1 and third subpixel Sp3 are of single-gate structure, and such that the TFT 50 of the fourth subpixel Sp4 having an identical function is of double-gate structure.

In the modification of the third embodiment as well, in addition to or instead of the compensation TFT 50b among the plurality of TFTs 50 in each subpixel Sp, the TFTs 50, except the compensation TFT 50b, that involve a problem, such as a bright spot, caused by a reduction in ON current property may be configured such that the channel width W3 of the TFT 50 of the third subpixel Sp3 is wider than the channel width W1 of the TFT 50 of the first subpixel Sp1 having an identical function, such that the TFTs 50 of the first subpixel Sp1 and third subpixel Sp3 are of single-gate structure, and such that the TFT 50 of the fourth subpixel Sp4 having an identical function is of double-gate structure.

The first to third embodiments have described, by way of example, that the organic EL layer 66 is individually provided for each subpixel Sp. The organic EL layer 66 may be shared among the plurality of subpixels Sp in continuity. The organic EL display 1 in this case may include, but not limited to, a color filter to display the color tone of each subpixel Sp.

The first to third embodiments have described, by way of example, that each pixel Px is composed of the subpixels Spr, Spg, and Spb of three colors. The number of colors of the subpixels Sp that constitute each pixel Px is not limited to three; four or more colors may be provided. Further, the foregoing has described, by way of example, that the subpixels Spr, Spg, and Spb of three colors that constitute each pixel Px are arranged in a stripe shape. The plurality of subpixels Sp may be arranged in other manners, such as a Pen Tile matrix.

The first to third embodiments have described, by way of example, that the seven TFTs 50 (the initialization TFT 50a, compensation TFT 50b, write TFT 50c, drive TFT 50d, power supply TFT 50e, emission control TFT 50f and anode discharge TFT 50g) provided in each subpixel Sp are all of top-gate structure. These seven TFTs 50 may be of bottom-gate structure. Further, the subpixel Sp may be provided with six or less TFTs 50, or eight or more TFTs 50.

The first to third embodiments have described, by way of example, that the pixel electrodes 62pe are anodes, and that the common electrode 68ce is a cathode. The pixel electrodes 62pe may be cathodes, and the common electrode 68ce may be an anode. The organic EL layer 66 in this case has an inverted stacked structure.

The first to third embodiments have described, by way of example, that the organic EL layer 66 has a 5-ply structure composed of the hole injection layer 66hi, hole transport layer 66ht, light-emitting layer 66em, electron transport layer 66et, and electron injection layer 66ei. The organic EL layer 66 may have a 3-ply structure composed of a hole injection-and-transport layer, a light-emitting layer, and an electron transport-and-injection layer, or the organic EL layer 66 can have any stacked structure.

The first to third embodiments have described, by way of example, the organic EL display 1 as a display device. The technique of the present disclosure is applicable to, for instance, a display device that includes a plurality of light-emitting elements that are driven by current. An example of this display device is a display device that includes quantum-dot light-emitting diodes (QLEDs), which are light-emitting elements included in a quantum-dot-containing layer.

The foregoing has described example preferred embodiments of the technique of the present disclosure. However, the technique of the present disclosure is not limited to the foregoing; the technique is also applicable to an embodiment with an appropriate modification, an appropriate replacement, an appropriate addition, an appropriate omission, or other things. Further, a new embodiment can be provided by combining the constituents described in the foregoing embodiments. One of ordinary skill in the art would understand that the foregoing embodiments can be further modified in various manners without departing from the purport of the technique of the present disclosure, and that such modifications also fall within the scope of the technique of the present disclosure.

### INDUSTRIAL APPLICABILITY

As described above, the technique of the present disclosure is useful for a display device that controls image display by operating a plurality of TFTs.

1. A display device comprising:
a substrate layer;
a thin-film transistor layer provided on the substrate layer; and
a light-emitting element layer provided on the thin-film transistor layer,
the light-emitting element layer including a light-emitting element provided in a subpixel constituting a display region,
the thin-film transistor layer including a plurality of thin-film transistors provided in the subpixel,
the plurality of thin-film transistors being configured to control an operation of the light-emitting element, to display an image in the display region by light emission from the light-emitting element,
wherein the subpixel located in a middle of the display region is a first subpixel, and the subpixel located at an outer edge of the display region is a second subpixel, and
wherein a channel length of at least one of the plurality of thin-film transistors provided in the second subpixel is shorter than a channel length of one of the plurality of thin-film transistors provided in the first subpixel and having an identical function.

2. A display device comprising:
a substrate layer;
a thin-film transistor layer provided on the substrate layer; and
a light-emitting element layer provided on the thin-film transistor layer,
the light-emitting element layer including a light-emitting element provided in a subpixel constituting a display region,
the thin-film transistor layer including a plurality of thin-film transistors provided in the subpixel,
the plurality of thin-film transistors being configured to control an operation of the light-emitting element, to display an image in the display region by light emission from the light-emitting element,
wherein the subpixel located in a middle of the display region is a first subpixel, and the subpixel located at an outer edge of the display region is a second subpixel, and
wherein a channel width of at least one of the plurality of thin-film transistors provided in the second subpixel is wider than a channel width of one of the plurality of thin-film transistors provided in the first subpixel and having an identical function.

3. A display device comprising:
a substrate layer;
a thin-film transistor layer provided on the substrate layer; and
a light-emitting element layer provided on the thin-film transistor layer,
the light-emitting element layer including a light-emitting element provided in a subpixel constituting a display region,
the thin-film transistor layer including a plurality of thin-film transistors provided in the subpixel,
the plurality of thin-film transistors being configured to control an operation of the light-emitting element, to display an image in the display region by light emission from the light-emitting element,
wherein the subpixel located in a middle of the display region is a first subpixel, and the subpixel located at an outer edge of the display region is a second subpixel,
wherein at least one of the plurality of thin-film transistors provided in the second subpixel is a thin-film transistor of multi-gate structure, and
wherein one of the plurality of thin-film transistors provided in the first subpixel and having a function identical to that of the thin-film transistor of multi-gate structure in the second subpixel is a thin-film transistor of single-gate structure.

4. The display device according to claim 1,
wherein the second subpixel located at the outer edge but a corner of the display region is a third subpixel, and the second subpixel located at the corner at the outer edge of the display region is a fourth subpixel, and
wherein a channel length of one of the plurality of thin-film transistors provided in the fourth subpixel is shorter than a channel length of one of the plurality of thin-film transistors provided in the third subpixel and having an identical function.

5. The display device according to claim 1,
wherein the second subpixel located at the outer edge but a corner of the display region is a third subpixel, and the second subpixel located at the corner at the outer edge of the display region is a fourth subpixel, and
wherein a channel width of one of the plurality of thin-film transistors provided in the fourth subpixel is wider than a channel width of one of the plurality of thin-film transistors provided in the third subpixel and having an identical function.

6. The display device according to claim 1,
wherein the second subpixel located at the outer edge but a corner of the display region is a third subpixel, and the second subpixel located at the corner at the outer edge of the display region is a fourth subpixel,
wherein one of the plurality of thin-film transistors provided in the fourth subpixel is a thin-film transistor of multi-gate structure, and
wherein one of the plurality of thin-film transistors provided in the third subpixel and having a function identical to that of the thin-film transistor of multi-gate structure in the fourth subpixel is a thin-film transistor of single-gate structure.

7. The display device according to claim 1,
wherein channel lengths of the plurality of thin-film transistors around an outer periphery of the display region decrease along with approach from a middle of the display region to the outer edge of the display region.

8. The display device according to claim 1,
wherein channel widths of the plurality of thin-film transistors around an outer periphery of the display region increase along with approach from a middle of the display region to the outer edge of the display region.

9. The display device according to claim 1,
wherein the plurality of thin-film transistors include a first thin-film transistor having a semiconductor layer composed of polysilicon, and a second thin-film transistor having a semiconductor layer composed of an oxide semiconductor.

10. The display device according to claim 1,
wherein the at least one thin-film transistor has a semiconductor layer composed of an oxide semiconductor.

11. The display device according to claim 1,
wherein the light-emitting element is an organic electroluminescence element.
